(19) United States
(12) Patent Application Publication
(10) Pub. No.: US 2019/0165226 A1
(43) Pub. Date: May 30, 2019

(54) SEMICONDUCTOR ELEMENT PACKAGE

(71) Applicant: LG INNOTEK CO., LTD., Seoul (KR)

(72) Inventors: Kyoung Un KIM, Seoul (KR); Young Jun KO, Seoul (KR); In Hyun CHO, Seoul (KR)

(21) Appl. No.: 16/098,340

(22) PCT Filed: May 2, 2017
(86) PCT No.: PCT/KR2017/004637

§ 371 Date: Nov. 1, 2018

(30) Foreign Application Priority Data
May 2, 2016 (KR) 10-2016-0053977
May 16, 2016 (KR) 10-2016-0059815
May 26, 2016 (KR) 10-2016-0064821

(51) Int. Cl. H01L 33/60; H01L 33/06; H01L 33/12; H01L 33/14; H01L 33/22; H01L 33/32; H01L 33/38; H01L 33/50; H01L 33/54; H01L 33/62; H01L 23/544

(52) U.S. Cl. CPC H01L 33/60; H01L 2933/0058; H01L 33/12; H01L 33/145; H01L 33/22; H01L 33/32; H01L 33/382; H01L 33/505; H01L 33/54; H01L 33/62; H01L 23/544; H01L 2933/0091; H01L 2933/0041; H01L 2933/005; H01L 33/06

(57) ABSTRACT

An embodiment provides a semiconductor element package which comprises: a semiconductor element comprising a first electrode pad and a second electrode pad, arranged on one surface thereof; a reflective member disposed on a side surface of the semiconductor element and having a sloping surface; a light-transmitting layer disposed on the sloping surface of the reflective member; and a wavelength conversion member disposed on the semiconductor element and the light-transmitting layer, wherein the sloping surface of the reflective member slopes such that the distance from the side surface of the semiconductor element increases along first direction, the first direction is a direction from one surface of the semiconductor element toward the other surface thereof, and, as the distance from the side surface of the semiconductor element increases, the thickness of the light-transmitting layer decreases and the thickness of the reflective member increases.

### TECHNICAL FIELD

Embodiments relate to a semiconductor element package.

### BACKGROUND ART

A light-emitting diode (LED) is a compound semiconductor element which converts electric energy into light energy and various colors may be implemented by controlling a composition ratio of the compound semiconductor element.

A nitride semiconductor light-emitting element has advantages of low power consumption, a semi-permanent lifetime, a fast response speed, safety, and environmental friendliness compared to conventional light sources such as fluorescent lamps and incandescent lamps. Accordingly, application of the nitride semiconductor light-emitting element has expanded to being applied as an LED backlight replacing a cold cathode fluorescent lamp (CCFL) which configures a backlight of a liquid crystal display (LCD) device, a white LED lighting device capable of replacing a fluorescent lamp or an incandescent lamp, a headlight of a vehicle, and traffic lights.

A chip scale package (CSP) may be manufactured by directly forming a wavelength conversion member on a flip chip. The CSP allows miniaturization of a package, but since the CSP emits light in all surfaces, it is required to adjust a direction of light emission as necessary. However, when some surfaces of the CSP are blocked, there is a problem in that light extraction efficiency (luminous flux) is reduced.

Further, in a light-emitting element package of the CSP, a wavelength conversion member completely surrounds an LED and an upper surface thereof generally has a square or rectangular shape, and thus it is difficult to distinguish first and second electrodes of the light-emitting element package.

### DISCLOSURE

### Technical Problem

Embodiments are directed to providing a semiconductor element package with improved light extraction efficiency.

Further, the embodiments are directed to providing a semiconductor element package capable of adjusting luminous flux and an angle of directivity.

Furthermore, the embodiments are directed to providing a semiconductor element package capable of being adjusted in size while maintaining a size of a chip.

Moreover, the embodiments are directed to providing a semiconductor element package capable of adjusting a color temperature.

In addition, the embodiments are directed to providing a semiconductor element package with improved reliability.

Additionally, the embodiments are directed to providing a semiconductor element package with easy polarity identification.

### Technical Solution

One aspect of the present invention provides a semiconductor element package including a light-emitting element including a plurality of electrode pads which are disposed on one surface of the light-emitting element, a wavelength conversion member disposed on one surface of the light-emitting element, and a reflective member disposed on a side surface of the light-emitting element, wherein the reflective member may have a sloping surface facing the side surface of the light-emitting element, the sloping surface of the reflective member may be declined away from the side surface of the light-emitting element toward a first direction, and the first direction may be a direction from the one surface to the other surface of the light-emitting element.

The semiconductor element package may further include a light-transmitting layer disposed on a gap space between the sloping surface and the side surface of the light-emitting element.

A viscosity of the light-transmitting layer may be in the range of 4000 mPa·s to 7000 mPa·s.

The sloping surface may have a curvature.

The curvature of the sloping surface may be in the range of 0.3 to 0.8.

The sloping surface may be formed to be convex in the first direction.

The sloping surface may be formed to be concave in the first direction.

A thickness of the light-transmitting layer may be decreased as being away from the side surface of the light-emitting element, and a thickness of the reflective member may be increased as being away from the side surface of the light-emitting element.

The wavelength conversion member may cover the other surface of the light-emitting element and an upper surface of the light transmitting layer.

### Advantageous Effects

According to the embodiments of the present invention, light extraction efficiency can be improved by a sloping surface of a reflective member.

Further, a size of the semiconductor element package can be controlled by adjusting an angle of the sloping surface of the reflective member.

Furthermore, luminous flux and angle of directivity can be controlled by adjusting the angle of the sloping surface.

Moreover, a color temperature of emitted light can be controlled.

The semiconductor element package according to the embodiments of the present invention may be configured such that a reflective member surrounding four side surfaces of a semiconductor element is disposed to cover a portion of a side surface of a wavelength conversion member disposed on an upper surface of the semiconductor element. Further, a diffusion member is disposed to cover upper surfaces of the wavelength conversion member and the reflective member such that the side surface of the wavelength conversion member can be completely surrounded by the reflective member and the diffusion member. Consequently, it is possible to efficiently prevent delamination of the wavelength conversion member from an upper surface of the semiconductor element.

In the semiconductor element package according to the embodiments of the present invention, polarities of first and second electrode pads exposed on a lower surface of the semiconductor element package can be easily determined by selectively removing the wavelength conversion member surrounding four side surfaces and the upper surface of the semiconductor element or by forming a recognition mark on the upper surface of the wavelength conversion member.

Various beneficial advantages and effects of the present invention are not limited by the detailed description and should be easily understood through a description of a detailed embodiment of the present disclosure.

### DESCRIPTION OF DRAWINGS

FIG. 1 is a plan view of a semiconductor element package according to a first embodiment of the present invention.

FIG. 2 is a cross-sectional view taken along the line A-A of FIG. 1.

FIG. 3 is a diagram illustrating the semiconductor element package with an increased size by adjusting an angle of a sloping surface.

FIG. 4 is a diagram illustrating the semiconductor element package with a decreased size by adjusting the angle of the sloping surface.

FIG. 5 is a cross-sectional view of a semiconductor element package according to a second embodiment of the present invention.

FIG. 6 is a diagram illustrating a modified embodiment of FIG. 5.

FIG. 7 is a diagram for describing a semiconductor element according to the first embodiment of the present invention.

FIG. 8 is a cross-sectional view of a semiconductor element package according to a third embodiment of the present invention.

FIG. 9 is a diagram for describing a semiconductor element of FIG. 8.

FIGS. 10A to 10D are diagrams for describing a method of manufacturing the semiconductor element package according to the first embodiment of the present invention.

FIG. 11A is a perspective view of a semiconductor element package according to a fourth embodiment of the present invention.

FIG. 11B is a cross-sectional view taken along the line I-I′ of FIG. 11A.

FIG. 12 is a cross-sectional view of a semiconductor element of FIG. 11B.

FIG. 13 is a cross-sectional view taken along the line I-I′ of a semiconductor element package according to a fifth embodiment of the present invention.

FIGS. 14A to 14F are cross-sectional views illustrating a method of manufacturing the semiconductor element package according to the fourth embodiment.

FIGS. 15A to 15H are cross-sectional views illustrating a method of manufacturing the semiconductor element package according to the fifth embodiment.

FIG. 16A is a perspective view of a semiconductor element package according to a sixth embodiment of the present invention.

FIG. 16B is a bottom view of FIG. 16A.

FIG. 16C is a plan view of FIG. 16A.

FIG. 16D is a cross-sectional view taken along the line I-I′ of FIG. 16A.

FIG. 16E is a cross-sectional view of a semiconductor element of FIG. 16B.

FIG. 16F is a photograph of the semiconductor element package according to the sixth embodiment of the present invention.

FIGS. 17A to 17C are perspective views of a semiconductor element package according to a seventh embodiment of the present invention.

FIG. 18A is a cross-sectional view taken along the line I-I′ of FIG. 17A.

FIG. 18B is a cross-sectional view taken along the line I-I′ of FIG. 17B.

FIG. 19A is a perspective view of a semiconductor element package according to an eighth embodiment of the present invention.

FIG. 19B is a cross-sectional view taken along the line I-I′ of FIG. 19A.

FIGS. 20A and 20B are perspective views of a semiconductor element package according to a ninth embodiment of the present invention.

FIG. 20C is a plan view of FIG. 20A.

FIG. 20D is a photograph of the semiconductor element package according to the ninth embodiment of the present invention.

FIG. 21 is a perspective view of a semiconductor element package according to a tenth embodiment of the present invention.

FIG. 22 is a perspective view of a mobile terminal according to an embodiment of the present invention.

### MODES OF THE INVENTION

The present embodiments may be modified in other forms or various embodiments may be combined with each other, and the scope of the present disclosure is not limited to each embodiment described below.

Although an item described in a specific embodiment is not described in other embodiment, unless otherwise described in the other embodiment or as long as there is no contradictory description therein, the item may be understood as being related to the other embodiment.

For example, when a feature for a configuration A is described in a specific embodiment and a feature for a configuration B is described in other embodiment, even when an embodiment in which the configuration A and the configuration B are combined is not explicitly described, unless otherwise described in the other embodiment or as long as there is no contradictory explanation therein, it should be understood that they will fall within the scope of the present disclosure.

In the description of the embodiments, when an element is described as being formed “on” or “under” another element, the terms “on” or “under” include the meaning of the two components bring in direct contact with each other and the meaning of one or more other components being indirectly disposed and formed between the two components. Also, when described as “over (upper) or below (lower), or on or under,” it may include not only an upward direction but also a downward direction with respect to one element.

Hereinafter, embodiments of the present disclosure will be fully described in detail which are suitable for implementation by those skilled in the art with reference to the accompanying drawings.

A semiconductor element may include various electronic elements such as a light emitting element, a light receiving element, and the like, and all of the light emitting element and the light receiving element may include a first conductivity type semiconductor layer, an active layer, and a second conductivity type semiconductor layer.

The semiconductor element according to the present embodiment may be a light-emitting element.

The light emitting element emits light by recombination of electrons and holes, and a wavelength of the light is determined by an inherent energy band gap of a material. Thus, the emitted light may be varied according to a composition of the material. Hereinafter, the semiconductor element of embodiments will be described as a light emitting element.

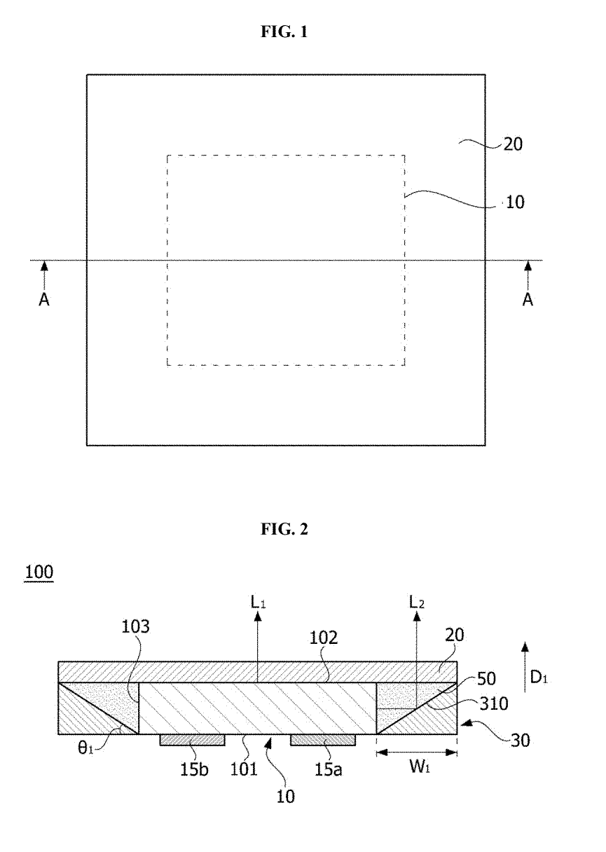

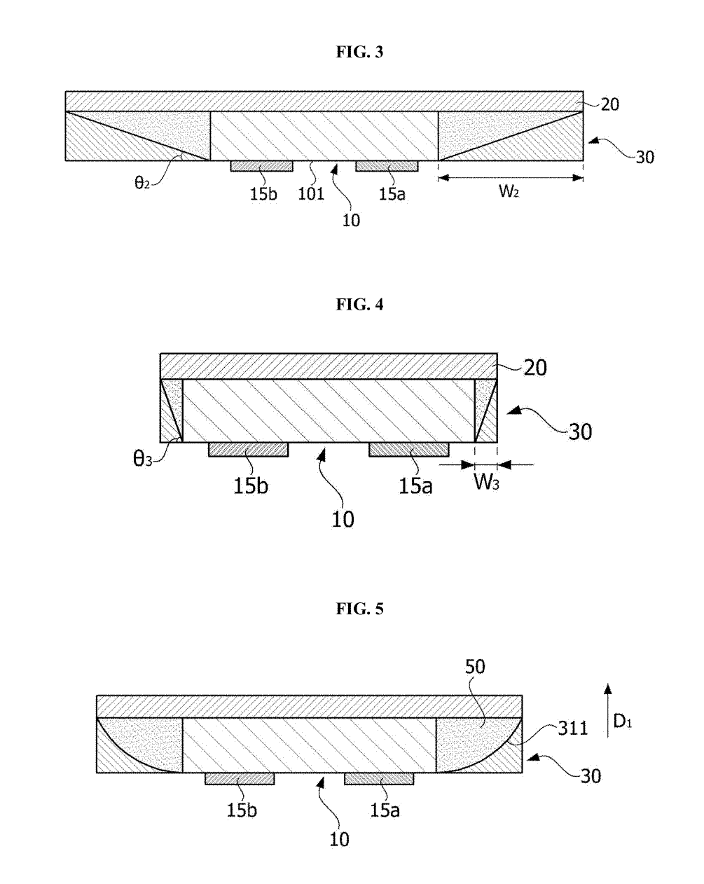

FIG. 1 is a plan view of a semiconductor element package according to a first embodiment of the present invention, and FIG. 2 is a cross-sectional view taken along the line A-A of FIG. 1.

Referring to FIGS. 1 and 2, the semiconductor element package according to the first embodiment includes a semiconductor element 10 including a plurality of electrode pads disposed on one surface thereof, a wavelength conversion member 20 disposed on an upper surface 102 of the semiconductor element 10, and a reflective member 30 disposed on a side surface 103 of the semiconductor element 10. The semiconductor element package may be a chip scale package (CSP).

The semiconductor element 10 may emit light in an ultraviolet (UV) wavelength range or in a blue wavelength range. The semiconductor element 10 may be a flip chip having a plurality of electrode pads disposed on a lower surface 101.

The wavelength conversion member 20 may cover the upper surface 102 and/or the side surface 103 of the semiconductor element 10. The wavelength conversion member 20 may be made of a polymer resin. The polymer resin may be one or more among a light-transmitting epoxy resin, a silicone resin, a polyimide resin, a urea resin, and an acrylic resin. For example, the polymer resin may be a silicone resin.

Wavelength conversion particles dispersed in the wavelength conversion member 20 may absorb light emitted from the semiconductor element 10 and convert the absorbed light into white light. For example, the wavelength converting particles may include one or more of phosphors and quantum dots (QDs).

The phosphor may include any one among an yttrium-aluminum-garnet (YAG)-based phosphor, a Tb₃Al₅O₁₂ (TAG)-based phosphor, a silicate-based phosphor, a sulfide-based phosphor, and a nitride-based phosphor, but embodiments are not particularly limited to those kinds of phosphors. When the semiconductor element 10 is a UV light-emitting diode (LED), a blue phosphor, a green phosphor, and a red phosphor may be selected as the phosphor. When the semiconductor element 10 is a blue LED, a green phosphor and a red phosphor may be selected as the phosphor, or a yellow phosphor (YAG) may be selected as the phosphor.

The reflective member 30 covers a side surface of the semiconductor element 10. The reflective member 30 has a sloping surface 310 facing the side surface 103 of the semiconductor element 10. The sloping surface 310 may be disposed to be inclined away from the side surface of the semiconductor element 10 toward a first direction D₁. Consequently, light L₂ emitted from the side surface of the semiconductor element 10 is emitted upward by the sloping surface 310 such that light extraction efficiency may be improved. The first direction D1 may be a direction from the lower surface 101 to the upper surface 102 of the semiconductor element 10.

The reflective member 30 may have a structure in which reflective particles are dispersed in a base material. The base material may be one or more among an epoxy resin, a silicone resin, a polyimide resin, a urea resin, and an acrylic resin. For example, the polymer resin may be a silicone resin. The reflective particles may include particles such as TiO₂ or SiO₂.

The reflective member 30 may include a first layer and a second layer which have different refractive indexes. The reflective member 30 may be formed in a distributed Bragg reflector (DBR) structure. The reflective member 30 includes a structure in which two dielectric layers having different refractive indexes are alternately disposed. For example, the reflective member 30 may include two among a SiO₂ layer, a Si₃N₄ layer, a TiO₂ layer, an Al₂O₃ layer, and a MgO layer. For example, the first layer may include a SiO₂ and the second layer may include TiO₂.

A light-transmitting layer 50 may be disposed on the sloping surface 310. The light-transmitting layer 50 is not particularly limited as long as it is a material which transmits light. The light-transmitting layer 50 may be any one among an epoxy resin, a silicone resin, a polyimide resin, a urea resin, and an acrylic resin. The light-transmitting layer 50 and the reflective member 30 may have the same refractive index, but the present invention is not limited thereto and the light-transmitting layer 50 and the reflective member 30 may have different refractive indexes.

The light-transmitting layer 50 is disposed in a gap space between the reflective member 30 and the side surface of the semiconductor element 10 such that a thickness of the light-transmitting layer 50 may be in inverse proportion to a thickness of the sloping surface 310. That is, the further away from the side surface of the semiconductor element 10, the thicker the thickness of the light-transmitting layer 50, such that the thickness of the light-transmitting layer 50 may become thinner.

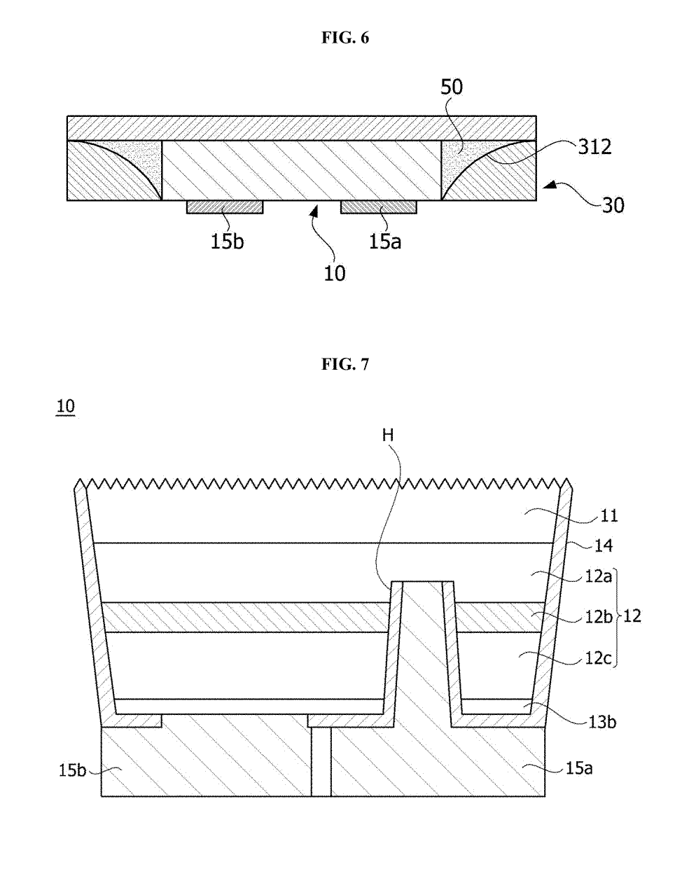

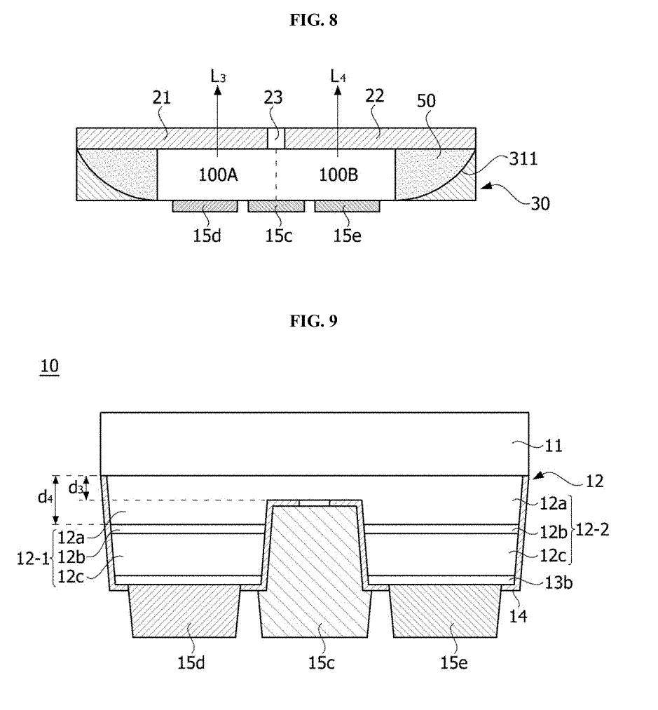

According to the present embodiment, a size of the semiconductor element package may be controlled by adjusting a width W₁ of the reflective member 30. Referring to FIG. 3, it is also possible to increase the size of the semiconductor element package by adjusting a width W₂ of the reflective member 30 to be wider. Alternatively, as shown in FIG. 4, the size of the semiconductor element package may be reduced by adjusting a width W₃ of the reflective member 30 to be narrower.

As shown in FIG. 3, when the width W₂ is manufactured to be wider, an angle θ₂ of the sloping surface 310 may be decreased, and as shown in FIG. 4, when the width W₃ is manufactured to be narrower, an angle θ₃ of the sloping surface 310 may be increased. According to the present embodiment, it is possible to manufacture packages having various sizes using the same size chip.

The following Table 1 is a table measuring relative luminous flux and an angle of directivity according to an inclination angle of the sloping surface 310.

TABLE 1

| | Angle | Relative | |
|---|---|---|---|
| | of sloping | luminous | Angle of |
| | surface (°) | flux (%) | directivity (°) |
| First experimental example | 15 | 112 | 135 |
| Second experimental example | 30 | 106 | 130 |
| Third experimental example | 45 | 100 | 128 |
| Fourth experimental example | 60 | 94 | 124 |
| Fifth experimental example | 75 | 88 | 120 |

Referring to Table 1, it can be seen that, as the angle of the sloping surface 310 is increased, the relative luminous flux decreases and the angle of directivity is decreased. Accordingly, it can be seen that desired luminous flux and a desired angle of directivity may be controlled by adjusting the angle of the sloping surface 310.

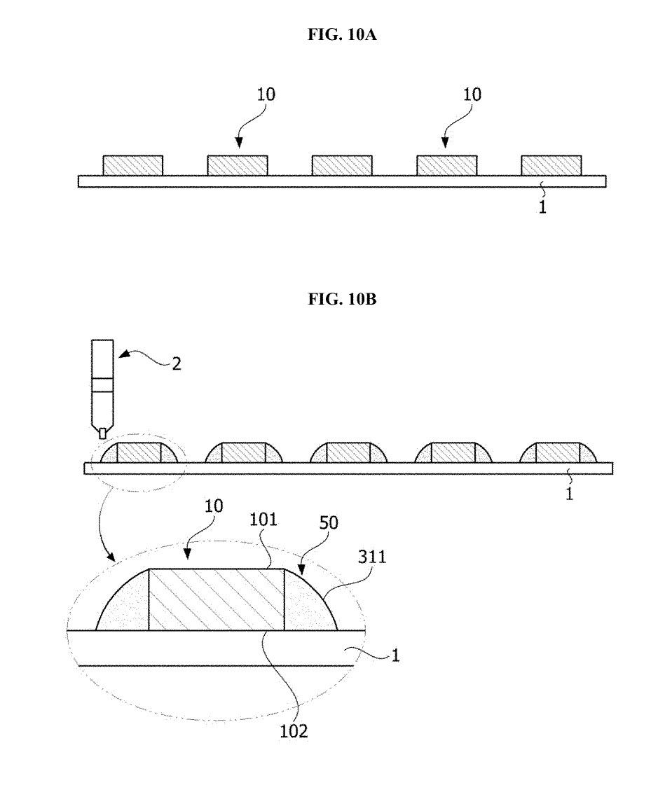

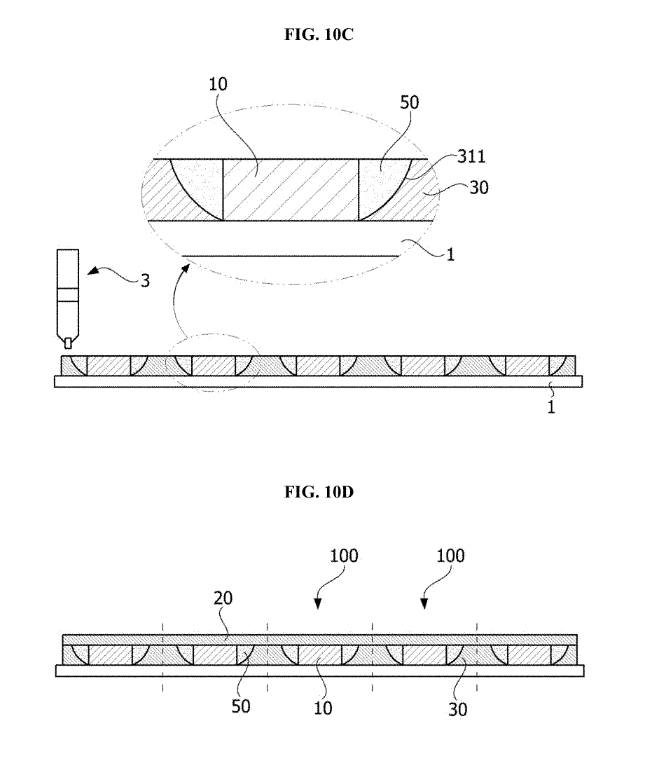

FIG. 5 is a cross-sectional view of a semiconductor element package according to a second embodiment of the present invention, and FIG. 6 is a diagram illustrating a modified embodiment of FIG. 5.

Referring to FIG. 5, a sloping surface 311 of the reflective member 30 may have a curvature in the semiconductor element 10 according to the present embodiment. Since the sloping surface 311 is an interface between the reflective member 30 and the light-transmitting layer 50, both of the reflective member 30 and the light-transmitting layer 50 may have curvatures. With such a configuration, efficiency with which light emitted from the side surface of the semiconductor element 10 is reflected upward may be increased.

The curvature of the sloping surface 311 may be in the range of 0.3R to 0.8R. When such a range is satisfied, reflection efficiency may be improved by about 3% as compared with a flat surface.

The sloping surface 311 may be formed to be concave in the first direction D1. However, the present invention is not limited thereto, and as shown in FIG. 6, the sloping surface 312 may be formed to be convex in the first direction.

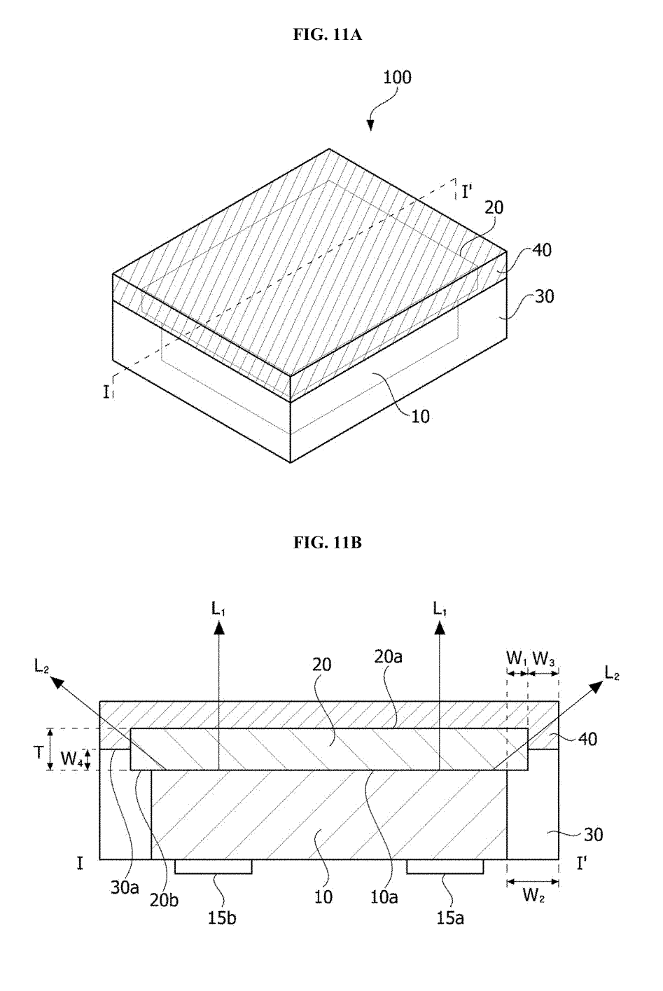

FIG. 7 is a diagram for describing a semiconductor element according to the first embodiment of the present invention.

Referring to FIG. 7, the semiconductor element 10 according to the present embodiment includes a light-emitting structure 12 disposed below a substrate 11, and a pair of electrode pads 15a and 15b disposed on one side of the light-emitting structure 12.

The substrate 11 includes a conductive substrate or an insulating substrate. The substrate 11 may be a material suitable for a semiconductor material growth or a carrier wafer. The substrate 11 may be formed of a material selected from among sapphire (Al₂O₃), SiC, GaAs, GaN, ZnO, Si, GaP, InP, and Ge, but the present invention is not limited thereto. The substrate 11 may be removed as necessary.

A buffer layer (not shown) may be further provided between a first conductivity type semiconductor layer 12a and the substrate 11. The buffer layer may alleviate a lattice mismatch between the substrate 11 and the light-emitting structure 12 provided on the substrate 11.

The buffer layer may be a combination of elements of a group III and group V or may include any one of GaN, InN, AlN, InGaN, AlGaN, InAlGaN, and AlInN. The buffer layer may be doped with a dopant, but the present invention is not limited thereto.

The buffer layer may be grown as a single crystal on the substrate 11, and the buffer layer grown with a single crystal may improve crystallinity of the first conductivity type semiconductor layer 12a.

The light-emitting structure 12 includes the first conductivity type semiconductor layer 12a, an active layer 12b, and a second conductivity type semiconductor layer 12c. Generally, the above-described light-emitting structure 12 and the substrate 11 may be cut together and divided into a plurality of pieces.

The first conductivity type semiconductor layer 12a may be formed of a compound semiconductor including a group III-V, a group II-VI, or the like and may be doped with a first dopant. The first conductivity type semiconductor layer 12a may be selected from semiconductor materials having a composition formula of Inₓ₁Al_{y1}Ga_{1-x1-y1}N (0≤x1≤1, 0≤y1≤1, and 0≤x1+y1≤1), e.g., GaN, AlGaN, InGaN, InAlGaN, and the like. Further, the first dopant may be an n-type dopant such as Si, Ge, Sn, Se, or Te. When the first dopant is an n-type dopant, the first conductivity type semiconductor layer 12a doped with the first dopant may be an n-type semiconductor layer.

The active layer 12b is a layer at which electrons (or holes) injected through the first conductivity type semiconductor layer 12a and holes (or electrons) injected through the second conductivity type semiconductor layer 12c meet. Electrons and holes may transit to a low energy level in the active layer 12b by being recombined, thereby generate light having a wavelength corresponding to the transition energy.

The active layer 12b may have any one of a single well structure, a multiple well structure, a single quantum well structure, a multi-quantum well (MQW) structure, a QD structure, and a quantum-wire structure, but is not limited thereto.

The second conductivity type semiconductor layer 12a may be formed on the active layer 12b, may be formed of a compound semiconductor including a group III-V, a group II-VI, or the like, and may be doped with a second dopant. The second conductivity type semiconductor layer 12c may be selected from materials having a composition formula of Inₓ₅Al_{y2}Ga_{1-x5-y2}N (0≤x5≤1, 0≤y2≤1, and 0≤x5+y2≤1) or may be selected from among AlInN, AlGaAs, GaP, GaAs, GaAsP, and AlGaInP. When the second dopant is a p-type dopant such as Mg, Zn, Ca, Sr, or Ba, the second conductivity type semiconductor layer 12c doped with the second dopant may be a p-type semiconductor layer.

An electron blocking layer (EBL) may be disposed between the active layer 12b and the second conductivity type semiconductor layer 12c. The EBL may block a flow of electrons supplied from the first conductivity type semiconductor layer 12a to the second conductivity type semiconductor layer 12c, thereby increasing probability of recombination between the electrons and the holes in the active layer 12b. An energy band gap of the electron blocking layer may be greater than an energy band gap of the active layer 12b and/or the second conductivity type semiconductor layer 12c.

The EBL may be selected from semiconductor materials having a composition formula of Inₓ₁Al_{y1}Ga_{1-x1-y1}N (0≤x1≤1, 0≤y1≤1, and 0≤x1+y1≤1), e.g., AlGaN, InGaN, InAlGaN, and the like, but the present invention is not limited thereto.

The light-emitting structure 12 includes a through-hole H formed in a direction from the second conductivity type semiconductor layer 12c to the first conductivity type semiconductor layer 12a. An insulating layer 14 may be formed on the through-hole H and a side surface of the light-emitting structure 12. In this case, the insulating layer 14 may expose one surface of the second conductivity type semiconductor layer 12c.

A second electrode 13b may be disposed on one surface of the second conductivity type semiconductor layer 12c. The second electrode 13b may include at least one among indium tin oxide (ITO), indium zinc oxide (IZO), indium zinc oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IrOₓ, RuOₓ, RuOₓ/ITO, Ni/IrOₓ/Au, and Ni/IrOₓ/Au/ITO, but the present invention is not limited thereto.

Further, the second electrode 13b may further include a metal selected from among In, Co, Si, Ge, Au, Pd, Pt, Ru, Re, Mg, Zn, Hf, Ta, Rh, Ir, W, Ti, Ag, Cr, Mo, Nb, Al, Ni, Cu, and WTi.

A first electrode pad 15a may be electrically connected to the first conductivity type semiconductor layer 12a. Specifically, the first electrode pad 15a may be electrically connected to the first conductivity type semiconductor layer 12a through the through-hole H.

A second electrode pad 15b may be electrically connected to the second conductivity type semiconductor layer 12c. Specifically, the second electrode pad 15b may be electrically connected to the second electrode 13b by passing through the insulating layer 14.

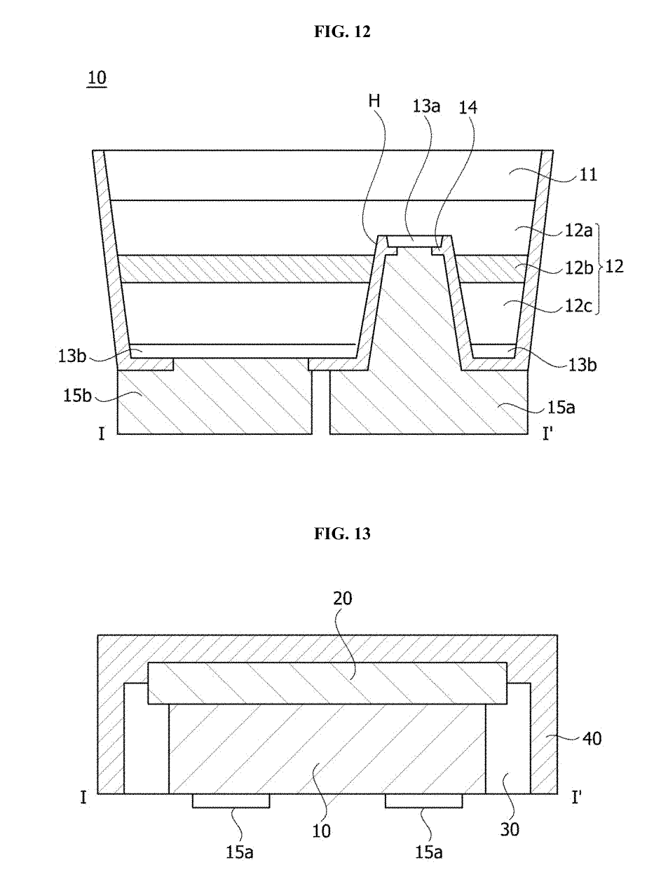

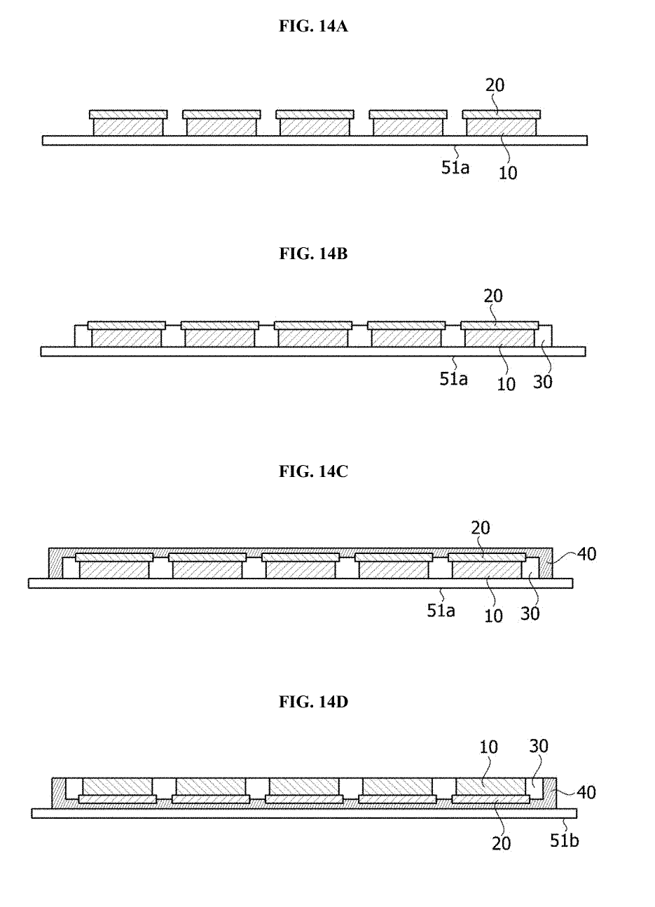

FIG. 8 is a cross-sectional view of a semiconductor element package according to a third embodiment of the present invention, and FIG. 9 is a diagram for describing a semiconductor element of FIG. 8.

The semiconductor element package according to the present embodiment includes the semiconductor element 10 having a first light-emitting portion 12-1 and a second light-emitting portion 12-2, the reflective member 30 covering the side surface 103 of the semiconductor element 10, a first wavelength conversion member 21 disposed on the first light-emitting portion 12-1, a second wavelength conversion member 22 disposed on the second light-emitting portion 12-2, and a reflection line 23 disposed between the first wavelength conversion member 21 and the second wavelength conversion member 22.

The semiconductor element 10 includes the first light-emitting portion 12-1 and the second light-emitting portion 12-2 which are capable of being individually driven. Consequently, the first light-emitting portion 12-1 and the second-light emitting portion 12-2 may selectively emit light by an external power source.

The semiconductor element 10 includes a common electrode 15c electrically connected to the first light-emitting portion 12-1 and the second light-emitting portion 12-2, a first driving electrode 15d electrically connected to the first light-emitting portion 12-1, and a second driving electrode 15e electrically connected to the second light-emitting portion 12-2. All of the common electrode 15c, the first driving electrode 15d, and the second driving electrode 15e may be disposed below the semiconductor element 10.

A wavelength conversion member includes the first wavelength conversion member 21 disposed on the first light-emitting portion 12-1, and the second wavelength conversion member 22 disposed on the second light-emitting portion 12-2. Light emitted from the first light-emitting portion 12-1 and passing through the first wavelength conversion member 21 may be converted into a first white light L₃. Further, light emitted from the second light-emitting portion 12-2 and passing through the second wavelength conversion member 22 may be converted into second white light L₄.

The first white light L₃ and the second white light L₄ may have different color temperatures. For example, the first white light L₃ may be warm white light, and the second white light L₄ may be cool white light. The warm white light may be defined as having a color temperature of about 3000K, and the cool white light may be defined as having a color temperature of about 6000K.

With such a configuration, it is possible to selectively provide required white lighting. For example, when warm white light is required, the first light-emitting portion 12-1 may be driven, and when cool white light is required, the second light-emitting portion 12-2 may be driven. Such a structure may be useful as a flash of a camera which requires color representation.

When a diffusion layer (not shown) is further disposed on the first wavelength conversion member 21 and the second wavelength conversion member 22, a quantity of light of each of the first white light L₃ and the second white light L₄ may also be adjusted to control a color temperature which is finally emitted.

The reflection line 23 may be disposed between the first wavelength conversion member 21 and the second wavelength conversion member 22 to separate the first wavelength conversion member 21 from the second wavelength conversion member 22. The reflection line 23 may also include a light absorbing material such as black carbon.

The first wavelength conversion member 21 and the second wavelength conversion member 22 may be manufactured by dispersing wavelength conversion particles in a polymer resin. The polymer resin may be one or more among a light-transmitting epoxy resin, a silicone resin, a polyimide resin, a urea resin, and an acrylic resin. For example, the polymer resin may be a silicone resin.

The wavelength conversion particles dispersed in the wavelength conversion member 20 may absorb light emitted from the semiconductor element 10 and convert the absorbed light into white light. For example, the wavelength converting particles may include one or more of phosphors and quantum dots (QDs). The kinds of the wavelength conversion particles are not particularly limited.

In order to differently control a color temperature, the kinds of wavelength conversion particles dispersed in the first wavelength conversion member 21 may be different from those of wavelength conversion particles dispersed in the second wavelength conversion member 22. However, the present invention is not limited thereto, and the kinds of the wavelength conversion particles dispersed in the first wavelength conversion member 21 may be identical to those of the wavelength conversion particles dispersed in the second wavelength conversion member 22. In this case, the color temperature may be controlled by differently adjusting controlling contents.

Referring to FIG. 9, the semiconductor element 10 includes the substrate 11, the light-emitting structure 12 disposed on the substrate, the insulating layer 14 covering the light-emitting structure 12, and the common electrode 15c electrically connected to the light-emitting structure 12 by passing through the insulating layer 14, and the first and second driving electrodes 15d and 15e.

The substrate 11 includes a conductive substrate or an insulating substrate. The substrate 11 may be a material suitable for a semiconductor material growth or a carrier wafer. The substrate 11 may be formed of a material selected from among Al₂O₃, SiC, GaAs, GaN, ZnO, Si, GaP, InP, and Ge, but the present invention is not limited thereto. The substrate 11 may be removed as necessary.

The light-emitting structure 12 includes the first conductivity type semiconductor layer 12a, a first active layer 12b disposed on and spaced apart from the first conductivity type semiconductor layer 12a, a second active layer 12b, a second-first conductivity type semiconductor layer 13b disposed below the first active layer 12b, and a second-second conductivity type semiconductor layer 12c disposed on the second active layer 12b.

The first light-emitting portion 12-1 and the second light-emitting portion 12-2 may share the first conductivity type semiconductor layer 12a. With such a structure, it is possible to prevent generation of a crack in the light-emitting structure 12 due to the relatively thick first conductivity type semiconductor layer 12a even without a substrate. Further, a current dispersion effect may be achieved.

The common electrode 15c may be connected to the first conductivity type semiconductor layer 12a, the first driving electrode 15d may be connected to the second-first conductivity type semiconductor layer 13b, and the second driving electrode 15e may be connected to the second-second conductivity type semiconductor layer 12c. In this case, an ohmic electrode may be further formed between each of the semiconductor layers and each of the electrodes.

In the semiconductor element 10 according to the present embodiment, the first light-emitting portion 12-1 and the second light-emitting portion 12-2 may be individually turned on. However, when one light-emitting portion is turned on, some light may be emitted to the other light-emitting portion through the first conductivity type semiconductor layer 12a. Consequently, a light interference problem may occur in which a light-emitting section which should not actually have been turned on may emit light.

A convex portion d4 and a concave portion d3 of the first conductivity type semiconductor layer 12a may be formed during mesa etching so as to separate the first light-emitting portion 12-1 from the second light-emitting portion 12-2. It may be ideal to completely separate the first light-emitting portion 12-1 from the second light emitting portion 12-2, but since the current dispersion effect by the first conductivity type semiconductor layer 12a is lost, a thickness of the light-emitting portion becomes thinner such that a crack may be easily generated.

A thickness of the concave portion d3 may be in the range of 10% to 50% relative to an overall thickness of the light-emitting structure. When the thickness of the concave portion d₃ is less than 10%, the concave portion d₃ is significantly thin, thus easily causing a crack during the manufacturing process, and when the thickness thereof exceeds 50%, there is a problem in that quantity of light incident into an adjacent light-emitting portion through the first conductivity type semiconductor layer 12a is increased. When the thickness of the concave portion d3 is in the range of 10% to 30% relative to the thickness of the light-emitting structure, most of the emitted light is emitted to the outside such that the light interference problem can be effectively solved.

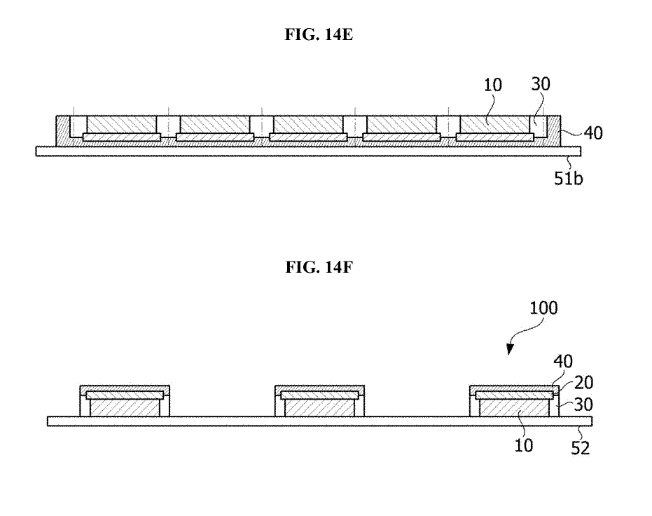

FIGS. 10A to 10D are diagrams for describing a method of manufacturing the semiconductor element package according to the first embodiment of the present invention.

Referring to FIGS. 10A and 10B, a plurality of semiconductor elements 10 may be disposed on an adhesive tape 1, and the light-transmitting layer 50 may be formed by injecting a light-transmitting resin onto the side surface of each of the plurality of semiconductor elements 10. In this case, when the light-transmitting layer 50 and the adhesive tape 1 have viscosity, respectively, the light-transmitting layer 50 may be fixed without flowing down from the side surface of each of the plurality of semiconductor elements 10. The viscosity of the light-transmitting layer 50 may be in the range of 4000 mPa·s to 7000 mPa·s, and the viscosity of the adhesive tape 1 may be about 80 gf/in.

The light-transmitting layer 50 may have a curvature by surface tension while being fixed to the side surface of each of the plurality of semiconductor elements 10. In this case, a curvature of the sloping surface 311 may be in the range of 0.3R to 0.8R.

Referring to FIG. 10C, the reflective member 30 may be injected into the light-transmitting layers 50. As described above, since a surface of the light-transmitting layer 50 has the curvature, the reflective member 30 filling in the light-transmitting layers 50 also has a curvature at an interface between reflective member 30 and the light-transmitting layers 50. The light-transmitting layer 50 and the reflective member 30 may use the same resin, and more reflective particles may be dispersed in the resin of the reflective member 30.

Thereafter, as shown in FIG. 10D, a wavelength conversion member 20 may be entirely formed on the semiconductor element 10 and may be cut to manufacture the plurality of semiconductor element packages 10.

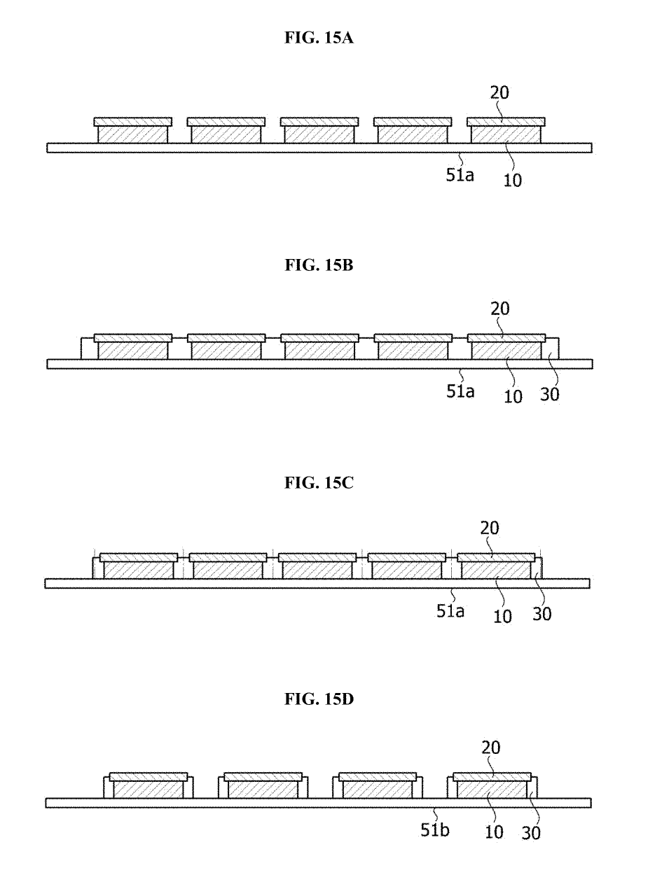

FIG. 11A is a perspective view of a semiconductor element package according to a fourth embodiment of the present invention, and FIG. 11B is a cross-sectional view taken along the line I-I′ of FIG. 11A.

Referring to FIGS. 11A and 11B, the semiconductor element package 100 of the present embodiment includes the semiconductor element 10, the wavelength conversion member 20 covering an upper surface 10a of the semiconductor element 10, the reflective member 30 covering the side surface of the semiconductor element 10 and a portion of a side surface of the wavelength conversion member 20, and a diffusion member 40 covering an upper surface 30a of the reflective member 30 and an upper surface 20a of the wavelength conversion member 20.

The semiconductor element package 100 may be a light-emitting element package having a CSP structure. For example, the semiconductor element 10 may be a light-emitting element of a flip chip structure in which the first and second electrode pads 15a and 15b are disposed on a lower surface of the semiconductor element 10. The structure of the semiconductor element 10 will be described below.

The wavelength conversion member 20 may cover the upper surface 10a of the semiconductor element 10. A thickness of the wavelength conversion member 20 may be in the range of 70 μm to 100 μm, but the present invention is not limited thereto. The wavelength conversion member 20 may be formed of a polymer resin in which wavelength conversion particles are dispersed. In this case, the polymer resin may be one or more selected from among a light-transmitting epoxy resin, a silicone resin, a polyimide resin, a urea resin, and an acrylic resin. For example, the polymer resin may be a silicone resin.

The wavelength conversion particles may absorb light emitted from the semiconductor element 10 and convert the absorbed light into white light. For example, the wavelength converting particles may include one or more of phosphors and QDs. Hereinafter, the wavelength converting particles will be described as the phosphors.

An edge of the wavelength conversion member 20 may have a shape protruding from an edge of the semiconductor element 10. This is because light emitted from the side surface of the semiconductor element 10 is converted into light of a specific wavelength range through a protruding region of the wavelength conversion member 20 and emitted to the outside of the semiconductor element package 10. For example, when the semiconductor element 10 emits light in a blue wavelength range, the light in the blue wavelength range may be converted into white light by the wavelength conversion member 20.

In this case, the light emitted from the semiconductor element 10 may include first light L₁ passing through the wavelength conversion member 20 in a region in close contact with the upper surface 10a of the semiconductor element 10, and second light L₂ passing through the protruding region of the wavelength conversion member 20 from the edge of the semiconductor element 10. Therefore, as in the present embodiment, a color sense of the white light may be improved in the semiconductor element package 100 having a structure in which the edge of the wavelength conversion member 20 protrudes from the edge of the semiconductor element 10. Further, when the wavelength conversion member 20 is disposed on the semiconductor element 10, a process margin may be secured.

The reflective member 30 may be disposed to surround four side surfaces of the semiconductor element 10 to reflect the light emitted from the side surface of the semiconductor element 10. Consequently, the light reflected by the reflective member 30 may be incident into the semiconductor element 10 again to be emitted through the upper surface 10a of the semiconductor element 10.

A height of the upper surface 30a of the reflective member 30 is higher than a height of the upper surface 10a of the semiconductor element 10 such that the reflective member 30 may be disposed to surround not only the side surface of the semiconductor element 10 but also a portion of the side surface of the wavelength conversion member 20. As described above, when the reflective member 30 is disposed to surround the portion of the side surface of the wavelength conversion member 20, it is possible to prevent delamination of the wavelength conversion member 20 from the semiconductor element 10.

In a general semiconductor element package, a wavelength conversion member is disposed on a semiconductor element and a side surface of the wavelength conversion member is directly exposed. Consequently, the wavelength conversion member is delaminated from an upper surface of the semiconductor element such that reliability of the semiconductor element package is degraded and at the same time, light extraction efficiency is also reduced.

In contrast, since the height of the upper surface 30a of the reflective member 30 is higher than the height of the upper surface 10a of the semiconductor element 10 and is lower than a height of the upper surface 20a of the wavelength conversion member 20, the semiconductor element package 100 of the above-described embodiment has a structure in which the portion of the side surface of the wavelength conversion member 20 is surrounded by the reflective member 30.

A difference W₄ in height between the upper surface 30a of the reflective member 30 and the upper surface 10a of the semiconductor element 10 may be ¼ times or more a thickness T of the wavelength conversion member 20. This is because the reflective member 30 sufficiently surrounds the side surface of the wavelength conversion member 20 to prevent delamination of the wavelength conversion member 20. Further, when the difference W₄ in height between the upper surface 30a of the reflective member 30 and the upper surface 10a of the semiconductor element 10 exceeds ¾ times the thickness T of the wavelength conversion member 20, the diffusion member 40 does not sufficiently surround the side surface of the conversion member 20.

Consequently, the difference W₄ in height between the upper surface 30a of the reflective member 30 and the upper surface 10a of the semiconductor element 10 may be in the range of ¼ times to ¾ times the thickness T of the wavelength conversion member 20, but the present invention is not limited thereto.

As described above, when the edge of the wavelength conversion member 20 protrudes from the edge of the semiconductor element 10, the reflective member 30 may have a first width W₂ and a second width W₃ which are different from each other. In this case, the first width W₂ is a width of a region, which is in contact with the side surface of the semiconductor element 10, of the reflective member 30, and the second width W₃ is a width of a region, which is in contact with the side surface of the wavelength conversion member 20, of the reflective member 30. Consequently, the second width W₃ of the reflective member 30 may be narrower than the first width W₂ of the reflective member 30 by a width W₁ of a region of the wavelength conversion member 20 protruding from the edge of the semiconductor element 10.

For example, when the width W₁ of the wavelength conversion member 20 protruding from the edge of the semiconductor element 10 is 50 μm and the first width W₂ of the reflective member 30 is 100 μm, the second width W₃ may be 50 μm.

Specifically, the second width W₃ of the reflective member 30 may be equal to or wider than the width W₁ of the region of the wavelength conversion member 20 protruding from the edge of the semiconductor element 10. This is because, when the second width W₃ of the reflective member 30 is narrower than the width W₁ of the region of the wavelength conversion member 20 protruding from the edge of the semiconductor element 10, the reflective member 30 may not sufficiently fix the side surface of the wavelength conversion member 20.

Consequently, in order to allow the reflective member 30 to sufficiently fix the side surface of the wavelength conversion member 20, the first width W₂ of the reflective member 30 may be two times or more the width W₁ of the region of the wavelength conversion member 20 protruding from the edge of the semiconductor element 10, but the present invention is not limited thereto.

The reflective member 30 may be made of a material capable of reflecting light. For example, the reflective member 30 may include phenyl silicone or methyl silicone. Further, the reflective member 30 may also include reflective particles. For example, the reflective member 30 may be a glass in which TiO₂ is dispersed.

The diffusion member 40 may be disposed to cover the upper surface 20a of the wavelength conversion member 20 to diffuse light which is emitted from the semiconductor element 10 and passes through the wavelength conversion member 20. Further, the diffusion member 40 may be disposed to surround the side surface of the wavelength conversion member 20.

Specifically, the diffusion member 40 may be disposed to completely cover the upper surface 20a of the wavelength conversion member 20 and the upper surface 30a of the reflective member 30, thereby compensating for a difference in height between the upper surface 20a of the wavelength conversion member 20 and the upper surface 30a of the reflective member 30. Consequently, a height between the upper surface 20a of the wavelength conversion member 20 and a lower surface 20b thereof, i.e., the side surface of the wavelength conversion member 20 is brought into contact with an interface in which the upper surface 30a of the reflective member 30 and a lower surface of the diffusion member 40 are in contact with each other such that the side surface of the wavelength conversion member 20 may be completely surrounded by the reflective member 30 and the diffusion member 40.

Accordingly, the wavelength conversion member 20 may also be completely surrounded by the reflective member 30, the diffusion member 40, and the semiconductor element 10. Therefore, the semiconductor element package 1000 of the present embodiment may efficiently prevent delamination of the wavelength conversion member 20.

For adhesion between the wavelength conversion member 20 and the diffusion member 40, the diffusion member 40 may include a material identical to the polymer resin included in the wavelength conversion member 20. For example, the diffusion member 40 may include a transparent silicone resin. In this case, the diffusion member 40 may be disposed to completely cover the upper surface of the reflective member 30, and the edge of the diffusion member 40 may coincide with the edge of the reflective member 30. In this case, it is possible to efficiently prevent delamination of the diffusion member 40 from the upper surface of the reflective member 30.

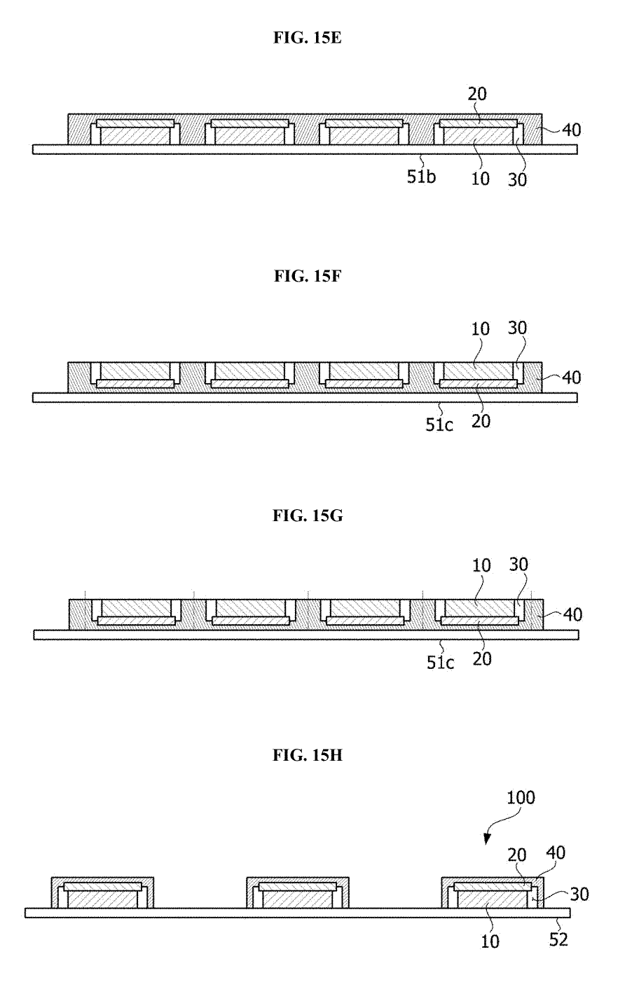

FIG. 12 is a cross-sectional view of the semiconductor element of FIG. 11B and illustrates the semiconductor element as a light-emitting element.

As shown in FIG. 12, the semiconductor element 10 of the present embodiment may be a light-emitting element including the light-emitting structure 12 disposed below the substrate 11, and the first and second electrode pads 15a and 15b disposed on one side of the light-emitting structure 12. In the present embodiment, the first and second electrode pads 15a and 15b are illustrated to be disposed below the light-emitting structure 12.

The substrate 11 includes a conductive substrate or an insulating substrate. The substrate 11 may be a material suitable for a semiconductor material growth or a carrier wafer. The substrate 11 may be formed of a material selected from among Al₂O₃, SiC, GaAs, GaN, ZnO, Si, GaP, InP, and Ge, but the present invention is not limited thereto. The substrate 11 may be removed as necessary.

The light-emitting structure 12 includes the first conductivity type semiconductor layer 12a, the active layer 12b, and the second conductivity type semiconductor layer 12c. Generally, the above-described light-emitting structure 12 and the substrate 11 may be cut and divided into a plurality of pieces.

The first conductivity type semiconductor layer 12a may be formed of a compound semiconductor including a group III-V, a group II-VI, or the like and may be doped with a first dopant. The first conductivity type semiconductor layer 12a may be selected from semiconductor materials having a composition formula of Inₓ₁Al_{y1}Ga_{1-x1-y1}N (0≤x1≤1, 0≤y1≤1, and 0≤x1+y1≤1), e.g., GaN, AlGaN, InGaN, InAlGaN, and the like. Further, the first dopant may be an n-type dopant such as Si, Ge, Sn, Se, or Te. When the first dopant is an n-type dopant, the first conductivity type semiconductor layer 12a doped with the first dopant may be an n-type semiconductor layer.

The active layer 12b is a layer at which electrons (or holes) injected through the first conductivity type semiconductor layer 12a and holes (or electrons) injected through the second conductivity type semiconductor layer 12c meet. Electrons and holes may transit to a low energy level in the active layer 12b by being recombined, thereby generating light having a wavelength corresponding to the transition energy.

The active layer 12b may have any one of a single well structure, a multiple well structure, a single quantum well structure, a multi-quantum well (MQW) structure, a QD structure, and a quantum-wire structure, but is not limited thereto.

The second conductivity type semiconductor layer 12c may be formed on the active layer 12b, may be formed of a compound semiconductor including a group III-V, a group II-VI, or the like, and may be doped with a second dopant. The second conductivity type semiconductor layer 12c may be selected from materials having a composition formula of Inₓ₅Al_{y2}Ga_{1-x5-y2}N (0≤x5≤1, 0≤y2≤1, and 0≤x5+y2≤1) or may be selected from among AlInN, AlGaAs, GaP, GaAs, GaAsP, and AlGaInP. When the second dopant is a p-type dopant such as Mg, Zn, Ca, Sr, or Ba, the second conductivity type semiconductor layer 12c doped with the second dopant may be a p-type semiconductor layer.

An EBL may be disposed between the active layer 12b and the second conductivity type semiconductor layer 12c. The EBL may block a flow of electrons supplied from the first conductivity type semiconductor layer 12a to the second conductivity type semiconductor layer 12c, thereby increasing probability of recombination between the electrons and the holes in the active layer 12b. An energy band gap of the electron blocking layer may be greater than an energy band gap of the active layer 12b and/or the second conductivity type semiconductor layer 12c. The EBL may be selected from semiconductor materials having a composition formula of Inₓ₁Al_{y1}Ga_{1-x1-y1}N (0≤x1≤1, 0≤y1≤1, and 0≤x1+y1≤1), e.g., AlGaN, InGaN, InAlGaN, and the like, but the present invention is not limited thereto.

The light-emitting structure 12 includes the through-hole H formed in a direction from the second conductivity type semiconductor layer 12c to the first conductivity type semiconductor layer 12a. The through-hole H may expose the first conductivity type semiconductor layer 12a on a bottom surface of the through-hole H and may expose the first and second semiconductor layers 12a and 12c and the active layer 12b on a side surface of the through-hole H. The first electrode 13a may be disposed to be electrically connected to the first conductivity type semiconductor layer 12a exposed by the through-hole H. Further, a second electrode 13b electrically connected to the second conductivity type semiconductor layer 12c may be disposed.

Each of the first and second electrodes 13a and 13b may include at least one among ITO, IZO, IZTO, IAZO, IGZO, IGTO, AZO, ATO, GZO, IrOₓ, RuOₓ, RuOₓ/ITO, Ni/IrOₓ/Au, and Ni/IrOₓ/Au/ITO, and the present invention is not limited thereto. Further, the first and second electrodes 13a and 13b may further include a metal selected from among In, Co, Si, Ge, Au, Pd, Pt, Ru, Re, Mg, Zn, Hf, Ta, Rh, Ir, W, Ti, Ag, Cr, Mo, Nb, Al, Ni, Cu, and WTi.

The insulating layer 14 may be disposed to surround the first and second semiconductor layers 12a and 12c and the active layer 12b which are exposed from the side surface of the through-hole H. As shown in the drawing, the insulating layer 14 may have a structure for further surrounding the side surface of the light-emitting structure 12, and a formation position of the insulating layer 14 is not limited thereto.

Further, the first and second electrodes 13a and 13b may be respectively electrically connected to the first and second electrode pads 15a and 15b.

Hereinafter, the semiconductor element package of another embodiment will be described in detail.

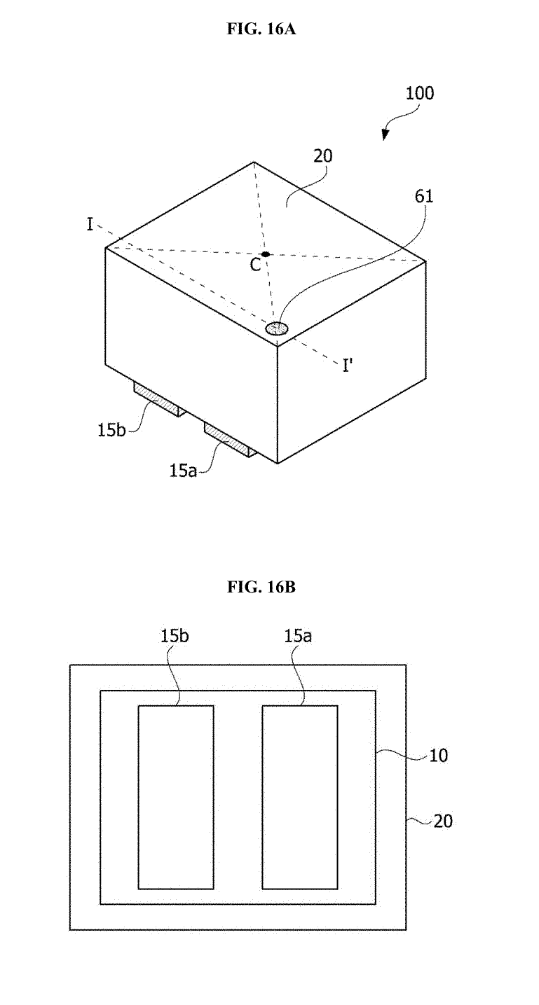

FIG. 13 is a cross-sectional view taken along the line I-I′ of a semiconductor element package according to a fifth embodiment of the present invention.

As shown in FIG. 13, the semiconductor element package according to the fifth embodiment may be configured such that the diffusion member 40 is disposed to surround the wavelength conversion member 20, the upper surface of the reflective member 30, and the side surface of the reflective member 30. In this case, since the diffusion member 40 completely surrounds the side surfaces of the wavelength conversion member 20 and the reflective member 30, a fixing force of the wavelength conversion member 20 may be improved.

As described above, the semiconductor element package 100 according to the present embodiment of the present invention may be configured such that the reflective member 30 surrounding four side surfaces of the semiconductor element 10 is disposed to cover a portion of the side surface of the wavelength conversion member 20 disposed on the upper surface of the semiconductor element 10. Further, since the diffusion member 40 is disposed to cover the upper surfaces of the wavelength conversion member 20 and the reflective member 30, the side surface of the wavelength conversion member 20 may be completely surrounded by the reflective member 30 and the diffusion member 40. Consequently, it is possible to prevent delamination of the wavelength conversion member 20 from the upper surface of the semiconductor element 10.

Hereinafter, a method of manufacturing the semiconductor element package of the present embodiment will be described in detail.

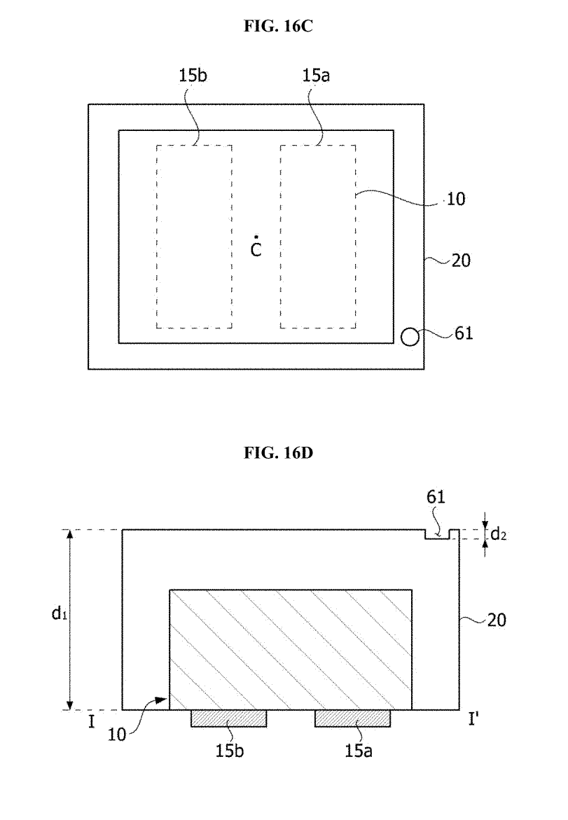

FIGS. 14A to 14F are cross-sectional views illustrating a method of manufacturing the semiconductor element package according to the fourth embodiment.

As shown in FIG. 14A, a plurality of semiconductor elements 10 may be disposed on a first fixing substrate 51a. The first fixing substrate 51a may be a tape having an adhesive force, but the present invention is not limited thereto.

Then, the wavelength conversion member 20 is disposed on an upper surface of each of the plurality of semiconductor elements 10. For example, when the wavelength conversion member 20 is in the form of a film, the wavelength conversion member 20 may be attached to the upper surface of each of the plurality of semiconductor elements 10. Specifically, in order to improve a process margin, and light extraction efficiency and a color characteristic of the semiconductor element package when the wavelength conversion member 20 is attached to the semiconductor element 10, an edge of the wavelength conversion member 20 may protrude more than an edge of each of the plurality of semiconductor elements 10.

As shown in FIG. 14B, the reflective member 30 is formed in a gap space each between the plurality of semiconductor elements 10. The reflective member 30 may be formed by applying a liquid-phase reflective material to cover each of the plurality of semiconductor elements 10 and curing the liquid-phase reflective material.

Further, as shown in FIG. 14C, the diffusion member 40 is formed to completely surround adjacent semiconductor elements 10 and between the wavelength conversion member 20 and the reflective member 30. The diffusion member 40 may be sprayed through spraying or may be applied in the form of a liquid phase. For example, the diffusion member 40 may be formed by applying a diffusion material onto the wavelength conversion member 20 and the reflective member 30 and curing the diffusion material using a mold.

As shown in FIG. 14D, the plurality of semiconductor elements 10 attached on the first fixing substrate 51a are transferred to a second fixing substrate 51b. At this point, the diffusion member 20 is brought into close contact with the second fixing substrate 51b such that a rear surface of each of the plurality of semiconductor elements 10 may be exposed. In this case, the rear surface of each of the plurality of semiconductor elements 10 is one surface through which the first and second electrode pads 15a and 15b of FIG. 11B are exposed.

As described above, the reason for transferring the plurality of semiconductor elements 10 to the second fixing substrate 51b is that, when the diffusion member 40 is disposed to completely cover the plurality of semiconductor elements 10, the wavelength conversion member 20, and the reflective member 30 as shown in FIG. 14C, it is difficult to distinguish the plurality of semiconductor elements 10 from the reflective member 30 on an upper surface of the diffusion member 40.

Accordingly, as shown in FIG. 14E, the plurality of semiconductor elements 10 and the reflective member 30 may be identified on the upper surface of the diffusion member 40 to cut between adjacent semiconductor elements 10 along a scribing line therebetween. The cutting between the adjacent semiconductor elements 10 may be performed by cutting the reflective member 30 and the diffusion member 40 of the adjacent semiconductor elements 10.

Further, as shown in FIG. 14F, the plurality of semiconductor elements 10 are transferred to a third fixing substrate 52. In this case, the plurality of semiconductor elements 10 are brought into close contact with the third fixing substrate 52 such that the diffusion member 40 may be exposed on an upper surface of the semiconductor element package 100. The third fixing substrate 52 may have elasticity to expend vertically and horizontally such that adjacent semiconductor element packages 100 may be spaced apart from each other.

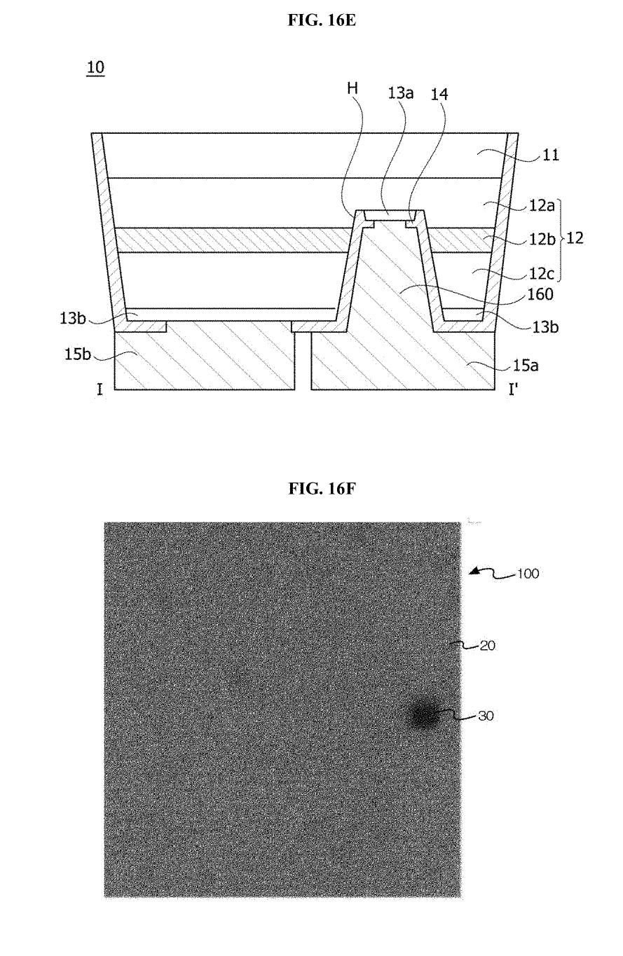

FIGS. 15A to 15H are cross-sectional views illustrating a method of manufacturing the semiconductor element package according to the fifth embodiment.

As shown in FIG. 15A, the plurality of semiconductor elements 10 may be disposed on the first fixing substrate 51a. The first fixing substrate 51a may be a tape having an adhesive force, but the present invention is not limited thereto.

Then, the wavelength conversion member 20 is disposed on an upper surface of each of the plurality of semiconductor elements 10. For example, when the wavelength conversion member 20 is in the form of a film, the wavelength conversion member 20 may be attached to the upper surface of each of the plurality of semiconductor elements 10. Specifically, in order to improve a process margin, and light extraction efficiency and a color characteristic of the semiconductor element package when the wavelength conversion member 20 is attached to the semiconductor element 10, the edge of the wavelength conversion member 20 may protrude from the edge of the semiconductor element 10.

As shown in FIG. 15B, the reflective member 30 is formed in a gap space each between the plurality of semiconductor elements 10. The reflective member 30 may be formed by applying a liquid-phase reflective material into a gap space each between the plurality of semiconductor elements 10 and curing the liquid-phase reflective material.

Next, as shown in FIG. 15C, adjacent semiconductor elements 10 may be cut along a scribing line therebetween. In this case, the reflective member 30 between the adjacent semiconductor elements 10 is cut. Then, as shown in FIG. 15D, the plurality of semiconductor elements 10 separated on the first fixing substrate 51a are re-disposed to be spaced apart from one another.

Subsequently, as shown in FIG. 15E, the diffusion member 40 is formed to completely surround the adjacent semiconductor elements 10 and between the wavelength conversion member 20 and the reflective member 30. The diffusion member 40 may be sprayed through spraying or may be applied in the form of a liquid phase. For example, the diffusion member 40 may be formed by applying a diffusion material onto the wavelength conversion member 20 and the reflective member 30 using a mold.

Then, as shown in FIG. 15F, the plurality of semiconductor elements 10 attached on the first fixing substrate 51a are transferred to a second fixing substrate 51b. At this point, the diffusion member 20 is brought into close contact with the second fixing substrate 51b such that a rear surface of each of the plurality of semiconductor elements 10 may be exposed. In this case, the rear surface of each of the plurality of semiconductor elements 10 is one surface through which the first and second electrode pads 15a and 15b of FIG. 11B are exposed.

Then, as shown in FIG. 15G, the plurality of semiconductor elements 10 and the reflective member 30 may be identified on the upper surface of the diffusion member 40 to cut between the adjacent semiconductor elements 10 along a scribing line therebetween.

Thereafter, as shown in FIG. 15H, the plurality of semiconductor elements 10 are transferred to a third fixing substrate 52. In this case, the plurality of semiconductor elements 10 are brought into close contact with the third fixing substrate 52 such that the diffusion member 40 may be exposed on an upper surface of the semiconductor element package 100. The third fixing substrate 52 may have elasticity to expend vertically and horizontally such that adjacent semiconductor element packages 100 may be spaced apart from each other.

A general method of manufacturing a semiconductor element package includes disposing a wavelength conversion film on a semiconductor element and transferring the semiconductor element to another fixing substrate in a state in which the wavelength conversion film is exposed. Thus, the wavelength conversion film may be delaminated from an upper surface of the semiconductor element.

On the other hand, in the method of manufacturing a semiconductor element package according to the present embodiment of the present invention, the semiconductor element 10 is transferred to another fixing substrate in a structure in which the upper surface and the side surface of the wavelength conversion film 20 are completely surrounded by the reflective member 30 and the diffusion member 40. Consequently, during the transferring, it is possible to efficiently prevent delamination of the wavelength conversion film 20 from the semiconductor element 10.

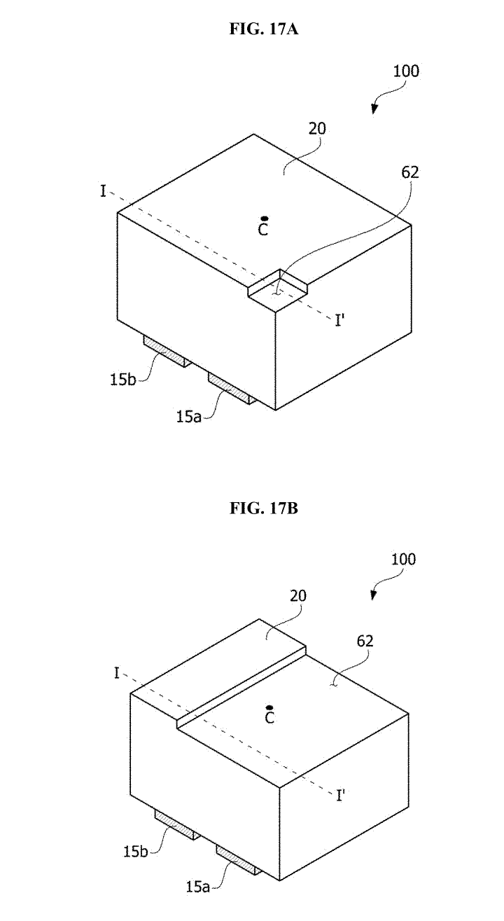

FIG. 16A is a perspective view of a semiconductor element package according to a sixth embodiment of the present invention. FIG. 16B is a bottom view of FIG. 16A, and FIG. 16C is a plan view of FIG. 16A. Further, FIG. 16D is a cross-sectional view taken along the line I-I′ of FIG. 16A.

As shown in FIGS. 16A to 16D, the semiconductor element package 100 according to the sixth embodiment of the present invention includes the semiconductor element 10, the wavelength conversion member 20 surrounding the side surface and the upper surface of the semiconductor element 10, and a recognition mark 61 formed on the upper surface of the wavelength conversion member 20 and configured to distinguish the first and second electrode pads 15a and 15b exposed on the lower surface of the semiconductor element 10. At least one recognition mark 61 may be formed on the upper surface of the wavelength conversion member 20 in the form of a groove formed by removing a portion of the upper surface of the wavelength conversion member 20.

The wavelength conversion member 20 may include a first region and a second region, which have different heights, at an asymmetrical position about a center C of the upper surface of the wavelength conversion member 20.

As in the present embodiment, the recognition mark 61, which distinguishes first and second electrode pads, may be the first region which is formed to be concave in a direction from the upper surface to the lower surface of the wavelength conversion member 20 and has a relatively low height.

Although the recognition mark 61 has been illustrated as a circular shape in the present embodiment, the shape of the recognition mark 61 is not limited thereto and may be selected from among an ellipse, a polygon, and the like.

The semiconductor element package 100 according to the present embodiment of the present invention may be a CSP. In the CSP, the first and second electrode pads 15a and 15b exposed on the lower surface of the semiconductor element package 100 may be electrically connected to lines of a circuit board such as a printed circuit board (PCB).

The semiconductor element 10 may be a light-emitting element emitting light in a UV wavelength range or in a blue wavelength range, but the present invention is not limited thereto. When the semiconductor element 10 is the light-emitting element, the light-emitting element may be a flip chip in which first and second electrodes (not shown) and the first and second electrode pads 15a and 15b are disposed on a lower surface of the light-emitting element, and a structure of the light-emitting element will be described below.

The wavelength conversion member 20 may be formed to surround four side surfaces of the semiconductor element 10 and the upper surface thereof. The wavelength conversion member 20 may be formed of a polymer resin in which wavelength conversion particles are dispersed. In this case, the polymer resin may be one or more selected from among a light-transmitting epoxy resin, a silicone resin, a polyimide resin, a urea resin, and an acrylic resin. For example, the polymer resin may be a silicone resin.

The wavelength conversion particles may absorb light emitted from the semiconductor element 10 and convert the absorbed light into white light. For example, the wavelength converting particles may include one or more of phosphors and QDs. Hereinafter, the wavelength converting particles will be described as the phosphors.

The phosphor may include any one among a YAG-based phosphor, a TAG-based phosphor, a silicate-based phosphor, a sulfide-based phosphor, and a nitride-based phosphor, but embodiments are not particularly limited to the kinds of phosphors. Each of the YAG phosphor and the TAG phosphor may be selected from (Y, Tb, Lu, Sc, La, Gd, or Sm)₃(Al, Ga, In, Si, or Fe)₅(O or S)₁₂:Ce, and the silicate-based phosphor may be used by selecting from (Sr, Ba, Ca, or Mg)₂SiO₄:(Eu, F, or Cl). Further, the sulfide-based phosphor may be selected from (Ca or Sr)S:Eu and (Sr, Ca, or Ba)(Al or Ga)₂S₄:Eu, and the nitride-based phosphor may be (Sr, Ca, Si, Al, or O)N:Eu (e.g., CaAlSiN₄:Eu β-SiAlON:Eu) or (Caₓ, M_{y})(Si or Al)₁₂(O or N)₁₆ which is Ca-α SiAlON:Eu base. At this point, M may be at least one material among Eu, Tb, Yb, and Er and may be selected from phosphor components satisfying 0.05<(x+y)<0.3, 0.02<x<0.27, and 0.03<y<0.3. A red phosphor may be a nitride-based phosphor including N (e.g., CaAlSiN₃:Eu) or a KSF (K₂SiF₆) phosphor.

As described above, in the CSP, the wavelength conversion member 20 completely surrounds the semiconductor element 10 such that, as shown in FIG. 16B, it is difficult to distinguish polarities of the first and second electrode pads 15a and 15b which are exposed on the lower surface of the semiconductor element package 100. Consequently, when the semiconductor element package 100 is mounted on a circuit board or the like, it is difficult to accurately determine a mounting direction of the semiconductor element package 100 such that a connection failure between the circuit board and the semiconductor element package 100 may occur. Further, it is difficult to determine a polarity of the semiconductor element package 100 even after the semiconductor element package 100 is mounted on the circuit board.

In order to prevent such problems, the present embodiment of the present invention may distinguish the polarities of the first and second electrode pads 15a and 15b using the recognition mark 61 formed on the upper surface of the wavelength conversion member 20 as shown in FIG. 16C. For example, when a polarity of an electrode pad of the first and second electrode pads 15a and 15b adjacent to the recognition mark 61 is (+), the polarity of the first electrode pad 15a may be (+) in the present embodiment.

To this end, the recognition mark 61 may be asymmetrically disposed about a center of the semiconductor element package 100. In this case, the center of the semiconductor element package 100 may coincide with the center C of the upper surface of the wavelength conversion member 20. As shown in the drawing, the recognition mark 61 may be formed on a lower right portion about the center C of the upper surface of the wavelength conversion member 20, and a formation position of the recognition mark 61 is not limited thereto. For example, as in the present embodiment, the recognition mark 61 may be formed in a region not overlapping with the semiconductor element 10 in a vertical direction.

The recognition mark 61 may be formed through a laser or punching, and the formation method of the recognition mark 61 is not limited thereto. For example, when the recognition mark 61 is formed using a laser, the laser is irradiated on the upper surface of the wavelength conversion member 20 to form the recognition mark 61 to be concave in a direction from the upper surface to the lower surface of the wavelength conversion member 20. In this case, a region on which the laser is irradiated, i.e., the recognition mark 61, may be displayed to be relatively darker than the wavelength conversion member 20 on the upper surface thereof. Consequently, since quality of the semiconductor element package 100 may be degraded as the region of the recognition mark 61 becomes wider, the region of the recognition mark 61 may be formed to be within 5% of an area of the upper surface of the wavelength conversion member 20, but the present invention is not limited thereto.

Specifically, when a difference d₂ in height between upper surfaces of the recognition mark 61 and the wavelength conversion member 20 is significantly large, a degree of light emission in the region in which the recognition mark 62 is formed may be different from a degree of light emission in the remaining area of the upper surface of the wavelength conversion member 20 such that a semiconductor characteristic of the element package 100 may be degraded. Consequently, the difference d₂ in height between the upper surfaces of the recognition mark 61 and the wavelength conversion member 20 may be within 1/10 of a thickness d₁ of the wavelength conversion member 20. Meanwhile, as in the present embodiment, when the recognition mark 61 is formed in a region not overlapping with the semiconductor element 10, the difference d₂ in height between the upper surfaces of the recognition mark 61 and the wavelength conversion member 20 may be easily changed, without being limited thereto.

FIG. 16E is a cross-sectional view of the semiconductor element of FIG. 16B and illustrates the semiconductor element as a light-emitting element.

As shown in FIG. 16E, the semiconductor element 10 of the present embodiment may be a light-emitting element including the light-emitting structure 12 disposed below the substrate 11, and the first and second electrode pads 15a and 15b disposed on one side of the light-emitting structure 12. In the present embodiment, the first and second electrode pads 15a and 15b are illustrated to be disposed below the light-emitting structure 12.

The substrate 11 includes a conductive substrate or an insulating substrate. The substrate 11 may be a material suitable for a semiconductor material growth or a carrier wafer. The substrate 11 may be formed of a material selected from among Al₂O₃, SiC, GaAs, GaN, ZnO, Si, GaP, InP, and Ge, but the present invention is not limited thereto. The substrate 11 may be removed as necessary.

The light-emitting structure 12 includes the first conductivity type semiconductor layer 12a, the active layer 12b, and the second conductivity type semiconductor layer 12c. Generally, the above-described light-emitting structure 12 and the substrate 11 may be cut and divided into a plurality of pieces.

The first conductivity type semiconductor layer 12a may be formed of a compound semiconductor including a group III-V, a group II-VI, or the like and may be doped with a first dopant. The first conductivity type semiconductor layer 12a may be selected from semiconductor materials having a composition formula of Inₓ₁Al_{y1}Ga_{1-x1-y1}N (0≤x1≤1, 0≤y1≤1, and 0≤x1+y1≤1), e.g., GaN, AlGaN, InGaN, InAlGaN, and the like. Further, the first dopant may be an n-type dopant such as Si, Ge, Sn, Se, or Te. When the first dopant is an n-type dopant, the first conductivity type semiconductor layer 12a doped with the first dopant may be an n-type semiconductor layer.

The active layer 12b is a layer at which electrons (or holes) injected through the first conductivity type semiconductor layer 12a and holes (or electrons) injected through the second conductivity type semiconductor layer 12c meet. Electrons and holes may transit to a low energy level in the active layer 12b by being recombined, thereby generating light having a wavelength corresponding to the transition energy.

The active layer 12b may have any one of a single well structure, a multiple well structure, a single quantum well structure, an MQW structure, a QD structure, and a quantum-wire structure, but is not limited thereto.

The second conductivity type semiconductor layer 12c may be formed on the active layer 12b, may be formed of a compound semiconductor including a group III-V, a group II-VI, or the like, and may be doped with a second dopant. The second conductivity type semiconductor layer 12c may be selected from materials having a composition formula of Inₓ₅Al_{y2}Ga_{1-x5-y2}N (0≤x5≤1, 0≤y2≤1, and 0≤x5+y2≤1) or may be selected from among AlInN, AlGaAs, GaP, GaAs, GaAsP, and AlGaInP. When the second dopant is a p-type dopant such as Mg, Zn, Ca, Sr, or Ba, the second conductivity type semiconductor layer 12c doped with the second dopant may be a p-type semiconductor layer.

An EBL may be disposed between the active layer 12b and the second conductivity type semiconductor layer 12c. The EBL may block a flow of electrons supplied from the first conductivity type semiconductor layer 12a to the second conductivity type semiconductor layer 12c, thereby increasing probability of recombination between the electrons and the holes in the active layer 12b. An energy band gap of the electron blocking layer may be greater than an energy band gap of the active layer 12b and/or the second conductivity type semiconductor layer 12c. The EBL may be selected from semiconductor materials having a composition formula of Inₓ₁Al_{y1}Ga_{1-x1-y1}N (0≤x1≤1, 0≤y1≤1, and 0≤x1+y1≤1), e.g., AlGaN, InGaN, InAlGaN, and the like, but the present invention is not limited thereto.

The light-emitting structure 12 includes the through-hole H formed in a direction from the second conductivity type semiconductor layer 12c to the first conductivity type semiconductor layer 12a. The through-hole H may expose the first conductivity type semiconductor layer 12a on a bottom surface of the through-hole H and may expose the first and second semiconductor layers 12a and 12c and the active layer 12b on a side surface of the through-hole H. The first electrode 13a may be disposed to be electrically connected to the first conductivity type semiconductor layer 12a exposed by the through-hole H. Further, a second electrode 13b electrically connected to the second conductivity type semiconductor layer 12c may be disposed.

Each of the first and second electrodes 13a and 13b may include at least one among ITO, IZO, IZTO, IAZO, IGZO, IGTO, AZO, ATO, GZO, IrOₓ, RuOₓ, RuOₓ/ITO, Ni/IrOₓ/Au, and Ni/IrOₓ/Au/ITO, and the present invention is not limited thereto. Further, the first and second electrodes 13a and 13b may further include a metal selected from among In, Co, Si, Ge, Au, Pd, Pt, Ru, Re, Mg, Zn, Hf, Ta, Rh, Ir, W, Ti, Ag, Cr, Mo, Nb, Al, Ni, Cu, and WTi.

The insulating layer 14 may be disposed to surround the first and second semiconductor layers 12a and 12c and the active layer 12b which are exposed from the side surface of the through-hole H. As shown in the drawing, the insulating layer 14 may have a structure for further surrounding the side surface of the light-emitting structure 12, and a formation position of the insulating layer 14 is not limited thereto.

The first and second electrodes 13a and 13b may be respectively and electrically connected to the first and second electrode pads 15a and 15b, and as shown in FIG. 16a, the first and second electrode pads 15a and 15b may be exposed on the lower surface of the semiconductor element package 100.

FIG. 16F is a photograph of the semiconductor element package according to the sixth embodiment of the present invention and illustrates a photograph of a light-emitting element package having a CSP structure.

As shown in FIG. 16F, it can be confirmed that the recognition mark 61 is capable of being visually distinguished from the wavelength conversion member 20 on an upper surface of the semiconductor element package according to the sixth embodiment of the present invention. For example, when the upper surface of the wavelength conversion member 20 is a yellow series, the recognition mark 61 may be displayed as a black color which is relatively darker than the upper surface of the wavelength conversion member 20.

The recognition mark 61 is formed on the upper surface of the wavelength conversion member 20 by irradiating a UV laser having a dimension of 50 μm×50 μm on the upper surface thereof. The kind of the laser forming the recognition mark 61 according to the sixth embodiment is not limited thereto.

Hereinafter, another embodiment of the semiconductor element package of the present invention will be described in detail.

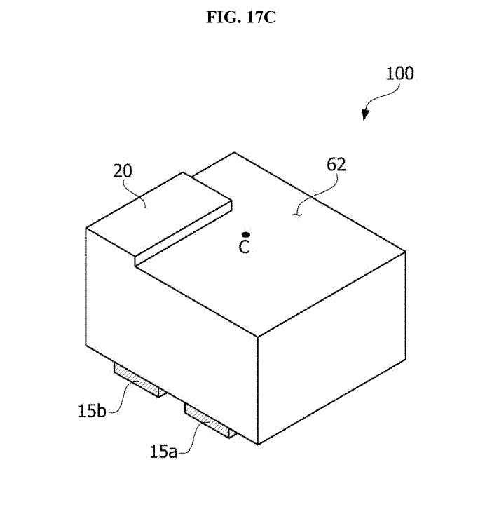

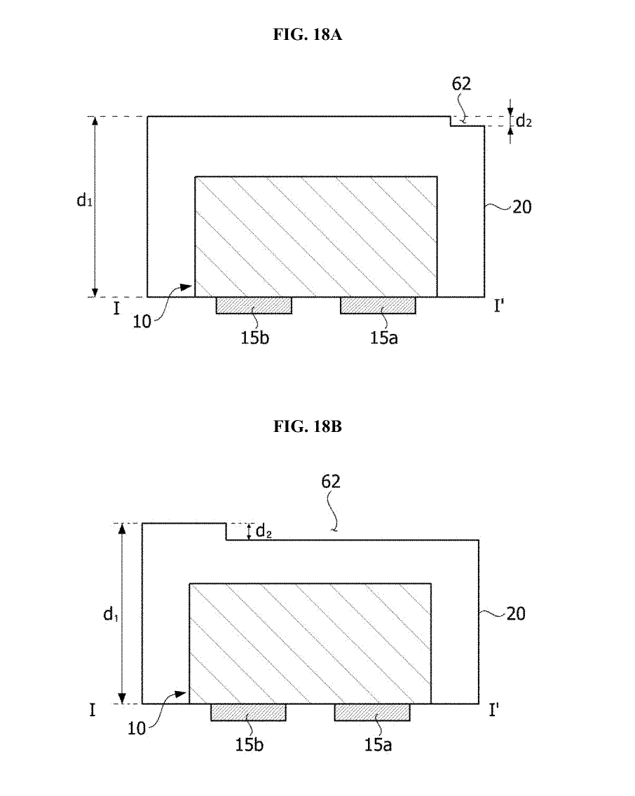

FIGS. 17A to 17C are perspective views of a semiconductor element package according to a seventh embodiment of the present invention. Further, FIG. 18A is a cross-sectional view taken along the line I-I′ of FIG. 17A, and FIG. 18B is a cross-sectional view taken along the line I-I′ of FIG. 17B.

As shown in FIGS. 17A to 17C, a recognition mark 62 may be formed at a corner of the upper surface of the wavelength conversion member 20. For example, the recognition mark 62 may include two among four edges of the upper surface of the wavelength conversion member 20 as shown in FIG. 17A or may include three among the four edges of the upper surface thereof as shown in FIG. 17B. Alternatively, as shown in FIG. 17C, the recognition mark 62 may include four among the four edges of the upper surface of the wavelength conversion member 20. Alternatively, although not shown in the drawings, the recognition mark 62 may include only one among four edges of the upper surface of the wavelength conversion member 20.

In this case, as shown in FIGS. 18A and 18B, when a difference d₂ in height between upper surfaces of the recognition mark 62 and the wavelength conversion member 20 is significantly large, a degree of light emission in the region in which the recognition mark 62 is formed may be different from a degree of light emission in the remaining area of the upper surface of the wavelength conversion member 20 such that a light emission characteristic of the element package 100 may be degraded. Consequently, the difference d₂ in height between the upper surfaces of the recognition mark 62 and the wavelength conversion member 20 may be within 1/10 of a thickness d₁ of the wavelength conversion member 20, but the present invention is not limited thereto.

Specifically, as described above, the recognition mark 62 of the semiconductor element package according to the seventh embodiment is distinguished from the wavelength conversion member 20 by a stepped level of the upper surface of the wavelength conversion member 20 so that there is no limitation on a region as in the recognition mark 61 according to the sixth embodiment. Consequently, a formation position of the recognition mark 62 may be easily changed.

When the recognition mark 62 includes the corner of the wavelength conversion member 20, the region of the recognition mark 62 is relatively large as compared with the case in which the recognition mark 62 is formed inside the upper surface of the wavelength conversion member 20 as shown in FIG. 17A. Therefore, in this case, when the wavelength conversion member 20 is formed to surround the semiconductor element 10, the recognition mark 62 may be formed on the wavelength conversion member 20 using a mold having the shape of the above-described recognition mark 62.

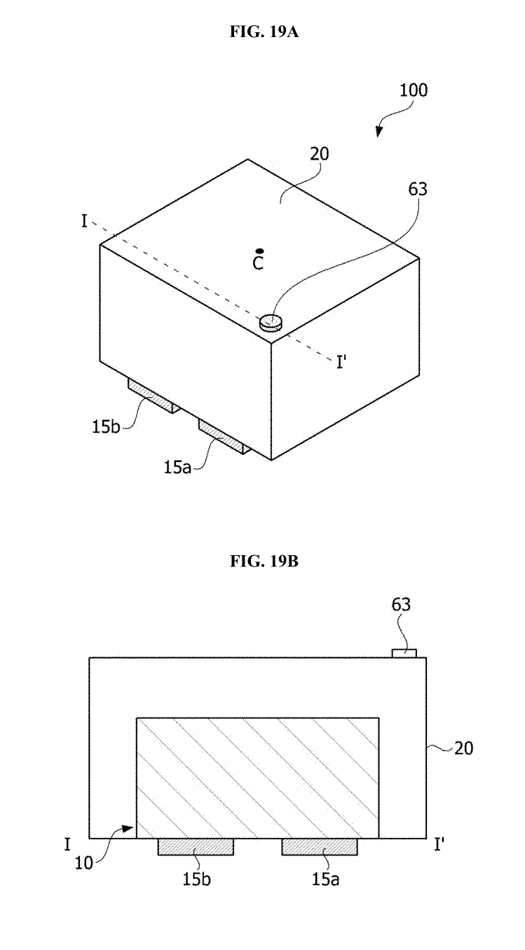

FIG. 19A is a perspective view of a semiconductor element package according to an eighth embodiment of the present invention, and FIG. 19B is a cross-sectional view taken along the line I-I′ of FIG. 19A.

As shown in FIGS. 19A and 19B, in the semiconductor element package according to the eighth embodiment of the present invention, a recognition mark 63 may be additionally formed on the wavelength conversion member 20. In this case, the recognition mark 63 may be coated on a flat upper surface of the wavelength conversion member 20 or may be attached to the flat upper surface thereof through an adhesive (not shown). The recognition mark 63 may be made of a material different from that of the wavelength conversion member 20. For example, the recognition mark 62 may include a reflective material. The recognition mark 63 may include white silicone such as phenyl silicone or methyl silicone and may further include reflective particles such as TiO₂, Al₂O₃, Nb₂O₅ and ZnO.

The recognition mark 63 may have a color distinguishable from the upper surface of the wavelength conversion member 20. For example, when the recognition mark 63 includes the above-described reflective material, a degree of light reflection of the formed region of the recognition mark 63 may be different from a degree of light reflection of the upper surface of the wavelength conversion member 20. Accordingly, a polarity of the semiconductor element package 100 may be easily distinguished through the recognition mark 63.

In the region in which the recognition mark 63 is formed, a degree of light emission is lower than a degree of light emission in the remaining region such that, as the region of the recognition mark 63 becomes wider, quality of the semiconductor element package 100 may be degraded. Consequently, the region of the recognition mark 63 may be within 5% of the area of the upper surface of the wavelength conversion member 20, but the present invention is not limited thereto. Further, although the recognition mark 63 has been illustrated as a circular shape in the present embodiment, the shape of the recognition mark 61 is not limited thereto and may be selected from among an ellipse, a polygon, and the like.

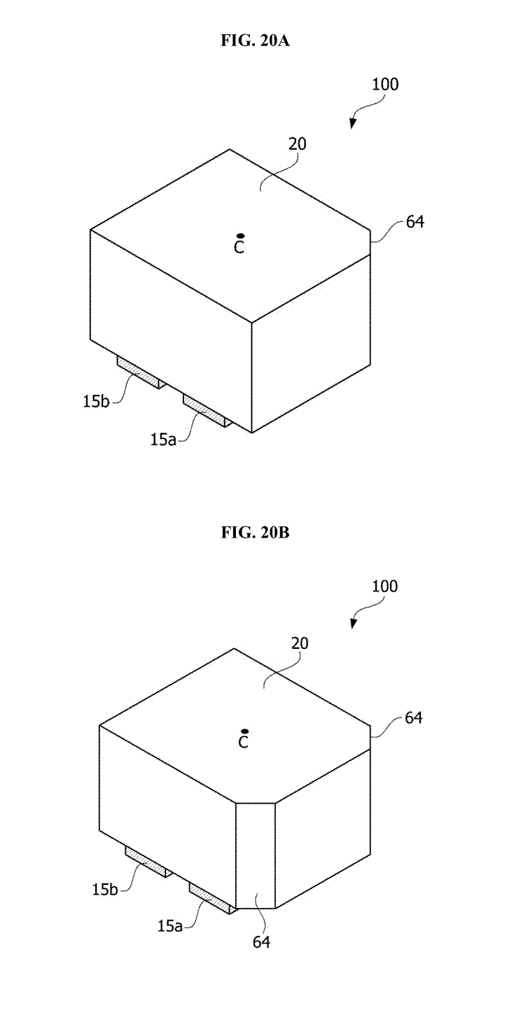

FIGS. 20A and 20B are perspective views of a semiconductor element package according to a ninth embodiment of the present invention, and FIG. 20C is a plan view of FIG. 20A. Further, FIG. 20D is a photograph of the semiconductor element package according to the ninth embodiment of the present invention.

As shown in FIGS. 20A and 20B, the semiconductor element package 100 of the ninth embodiment of the present invention may have a polygonal structure in which an upper surface of the wavelength conversion member 20 is surrounded by five or more line segments. In this case, the upper surface of the wavelength conversion member 20 may have an asymmetric polygonal structure about a center C of the upper surface thereof.

As shown in FIG. 20A, the upper surface of the wavelength conversion member 20 may be an asymmetrical pentagon about the center C of the upper surface thereof, and an area of the asymmetrical upper surface of the wavelength conversion member 20 may be recognized as a recognition mark 64. Further, as shown in FIG. 20B, the upper surface of the wavelength conversion member 20 may be an asymmetrical hexagon about the center C of the upper surface thereof. In this case, an area of the asymmetrical upper surface of the wavelength conversion member 20 may be recognized as the recognition mark 64.

For example, when a polarity of an electrode pad of the first and second electrode pads 15a and 15b adjacent to the recognition mark 64 is (+), the polarity of the first electrode pad 15a may be (+) in the present embodiment.

The semiconductor element package 100 according to the ninth embodiment of the present invention is formed by removing a portion of the wavelength conversion member 20 and, as the removal area of the wavelength conversion member 20 is increased, uniformity of light emission of the semiconductor element package 100 may be degraded. Consequently, as shown in FIG. 20C, a transverse length L₃ of an area A, which will be removed, may be within 1/10 of a transverse length L₁ of the semiconductor element package 100, and a longitudinal length L₃ of the area A, which will be removed, may also be within 1/10 of a longitudinal length L₁ of the semiconductor element package 100, but the present invention is not limited thereto.

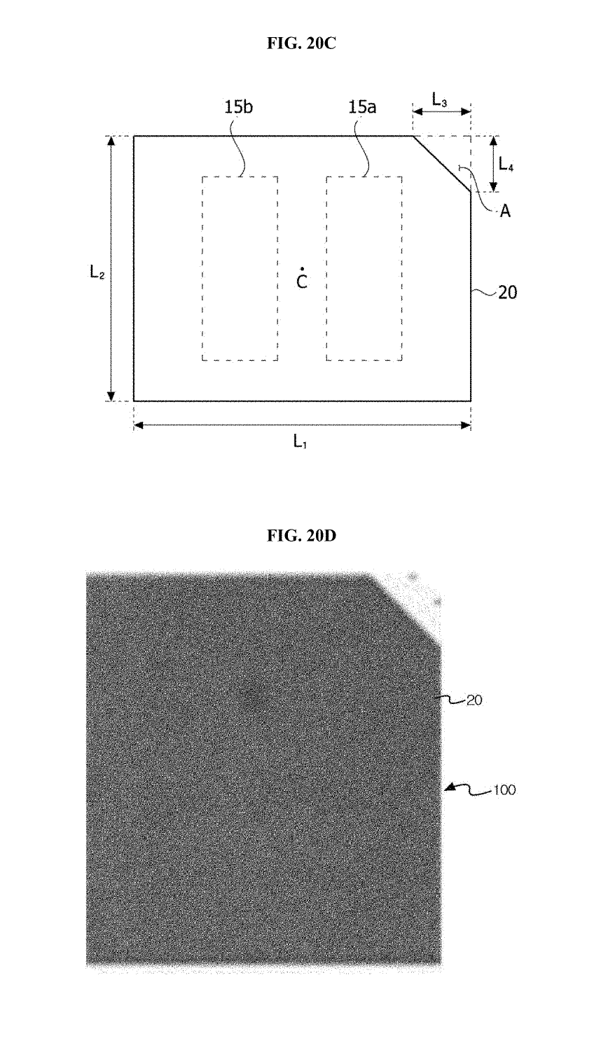

FIG. 21 is a perspective view of a semiconductor element package according to a tenth embodiment of the present invention.

As shown in FIG. 21, the semiconductor element package 100 according to the tenth embodiment of the present invention may configured such that a portion of the side surface of the wavelength conversion member 20 includes a curved surface. Thus, an edge of the upper surface of the wavelength conversion member 20 may have a curvature in at least one region. In the present embodiment, it has been illustrated that a region corresponding to one vertex, at which two among four edges of the upper surface of the wavelength conversion member 20 meet, has a curvature. In this case, the region having the curvature is an asymmetrical position about a center C of the upper surface of the wavelength conversion member 20. Consequently, in the semiconductor element package 100 according to the tenth embodiment of the present invention, a position of the asymmetrical upper surface of the wavelength conversion member 20 may be recognized as a recognition mark 65.

As described above, in the semiconductor element package 100 according to the embodiments of the present invention, polarities of the first and second electrode pads 15a and 15b exposed on the lower surface of the semiconductor element package 100 can be easily determined by selectively removing the wavelength conversion member 20 surrounding the four side surfaces and the upper surface of the semiconductor element 10 or by forming a recognition mark on the upper surface of the wavelength conversion member 20.

The semiconductor element package 100 may be used as a light source of a lighting system. For example, the semiconductor element package 100 may be used as a light source of an image display device or a lighting device.

When the semiconductor element package 100 is used as a backlight unit of the image display device, the semiconductor element package 100 may be used as an edge-type backlight unit or a direct-type backlight unit. When the semiconductor element package 100 is used as a light source of the lighting device, the semiconductor element package 100 may be used as a lamp instrument or may be used in the form of a bulb type, and the semiconductor element package 100 may also be used as a light source of a mobile terminal.

A light-emitting element includes a laser diode in addition to the above-described light-emitting element.

Like the light emitting device, the laser diode may include the first conductivity type semiconductor layer, the active layer, and the second conductivity type semiconductor layer of the above-described structure. Further, the laser diode uses an electro-luminescence phenomenon in which light is emitted when a current flows after a p-type first conductivity type semiconductor and an n-type second conductivity type semiconductor are bonded, but there are differences in directivity and phase of light between the light emitting device and the laser diode. That is, the laser diode may emit light having the same phase in the same direction at a specific single wavelength (i.e., a monochromatic beam) using a phenomenon referred to as stimulated emission and a constructive interference phenomenon, and, with the above-described characteristic, the laser diode may be used for an optical communication, medical equipment, semiconductor processing equipment, and the like.

An example of a light receiving device may include a photodetector which is a kind of transducer that detects light and converts an intensity of the detected light into an electric signal. Such a photodetector may include a photocell (silicon or selenium), a photoconductive element (cadmium sulfide or cadmium selenide), a photodiode (PD) (e.g., a PD having a peak wavelength in a visible blind spectral region or in a true blind spectral region), a phototransistor, a photomultiplier, a photoelectric tube (vacuum or gas filling), an infra-red (IR) detector, or the like, but the present invention is not limited thereto.

Further, a semiconductor element such as the photodetector may be manufactured using a direct bandgap semiconductor of which photoconversion efficiency is generally high. Alternatively, the photodetector has a variety of structures, and includes a pin-type photodetector using a pn junction which is a most general structure, a Schottky photodetector using a Schottky junction, and a metal-semiconductor-metal (MSM) type photodetector.

Like the semiconductor element, the PD may include the first conductivity type semiconductor layer, the active layer, and the second conductivity type semiconductor layer of the above-described structure and may be formed of a pn junction or a pin structure. The photodiode operates by applying a reverse bias or a zero bias, and, when light enters the photodiode, electrons and holes are generated and thus a current flows. At this point, a magnitude of the current may be approximately proportional to an intensity of the light incident into the photodiode.

A photovoltaic cell or a solar cell is a kind of a photodiode and may convert light into a current. Like the semiconductor element, the solar cell may include the first conductivity type semiconductor layer, the active layer, and the second conductivity type semiconductor layer of the above-described structure.

Further, the PD may be used as a rectifier of an electronic circuit through a rectifying characteristic of a general diode using a pn junction, and may be applied to an oscillation circuit and the like by being employed to a microwave circuit.

Further, the above-described semiconductor element is not necessarily implemented as a semiconductor, and in some cases, the semiconductor element may further include a metal material. For example, the semiconductor element such as the light receiving element may be implemented using at least one among Ag, Al, Au, In, Ga, N, Zn, Se, P, and As and may also be implemented using a semiconductor material doped with a p-type or n-type dopant or an intrinsic semiconductor material.

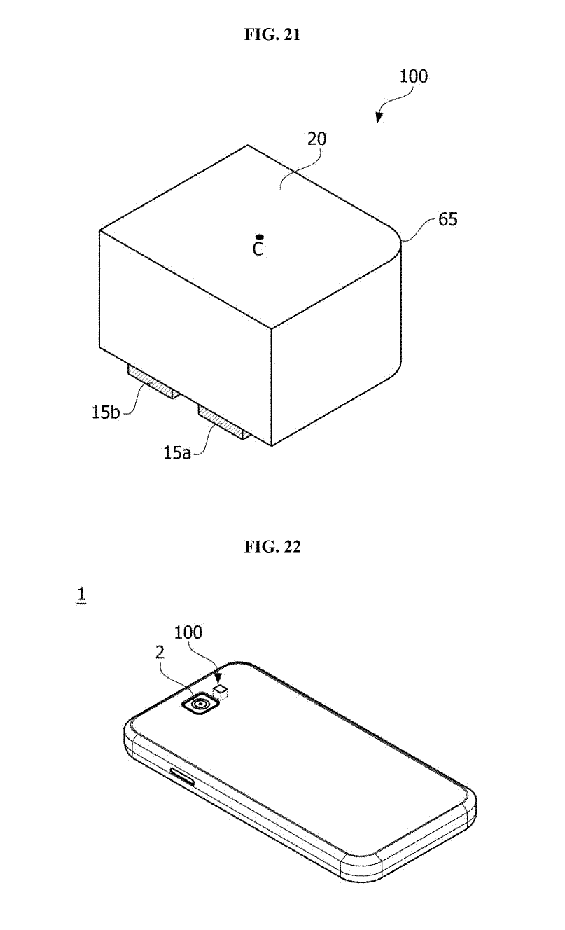

Referring to FIG. 22, a camera flash of a mobile terminal 1 may include a light source module employing the semiconductor element package 10 of the embodiments of the present invention. The semiconductor element package 10 may be disposed close to a camera 2. The semiconductor element package according to the embodiments of the present invention may simultaneously implement cool white light and warm white light to provide optimal lighting required for image acquisition. Further, the CSP package according to the embodiments of the present invention has an angle of directivity corresponding to an angle of view of the camera such that there is an advantage in that light loss is low.

It should be understood that embodiments of the present invention are not limited to the above described embodiments and the accompanying drawings, and various substitutions, modifications, and alterations can be devised by those skilled in the art that without departing from the technical spirit of the embodiment described herein. Illustratively, a configuration in which the recognition mark of the sixth embodiment is added to the first to fifth embodiments will fall within the scope of the present invention.

1. A semiconductor element package comprising:
a semiconductor element including first and second electrode pads which are disposed on one surface of the semiconductor element;
a reflective member having a sloping surface disposed on a side surface of the semiconductor element;
a light-transmitting layer disposed on the sloping surface of the reflective member; and
a wavelength conversion member disposed on the semiconductor element and the light-transmitting layer,
wherein the sloping surface of the reflective member is declined away from a side surface of the semiconductor element toward a first direction, and the first direction is a direction from one surface to the other surface of the semiconductor element; and
a thickness of the light-transmitting layer is decreased as being away from the side surface of the semiconductor element, and a thickness of the reflective member is increased as being away from the side surface of the semiconductor element.

2. The semiconductor element package of claim 1, wherein the sloping surface has a curvature in a range of 0.3 to 0.8.

3. The semiconductor element package of claim 2, wherein the sloping surface is formed to be convex or concave in the first direction.

4. The semiconductor element package of claim 1, wherein a viscosity of the light-transmitting layer is in a range of 4000 mPa·s to 7000 mPa·s.

5. The semiconductor element package of claim 1, further comprising a diffusion member disposed to cover upper surfaces of the reflective member and the wavelength conversion member,
wherein the reflective member surrounds four side surfaces of the semiconductor element, a height of an upper surface of the reflective member is higher than a height of an upper surface of the semiconductor element and is lower than a height of an upper surface of the wavelength conversion member.

6. The semiconductor element package of claim 5, wherein an interface at which the upper surface of the reflective member is brought into close contact with a lower surface of the diffusion member is in contact with a side surface of the reflective member.

7. The semiconductor element package of claim 1, wherein the wavelength conversion member includes a first region and a second region which have different heights at an asymmetrical position about a center of an upper surface of the wavelength conversion member, and the first region is a recognition mark which distinguishes a first electrode pad from a second electrode pad.

8. The semiconductor element package of claim 7, wherein the recognition mark is visually distinguished from the upper surface of the wavelength conversion member.

9. The semiconductor element package of claim 8, wherein the recognition mark is relatively dark compared to a remaining area of the upper surface of the wavelength conversion member.

10. The semiconductor element package of claim 7, wherein a region of the recognition mark is within 5% of an area of the upper surface of the wavelength conversion member.
